(19) United States
(12) Patent Application Publication
(10) Pub. No.: US 2019/0362914 A1
(43) Pub. Date: Nov. 28, 2019

(54) DETERMINATION SYSTEM, DETERMINATION METHOD, AND DETERMINATION PROGRAM

(71) Applicant: Panasonic Intellectual Property Management Co., Ltd., Osaka-shi, Osaka (JP)

(72) Inventors: Kojiro Yano, Okayama (JP); Kenichi Matsumoto, Okayama (JP); Ryo Nakae, Okayama (JP); Masanori Mitsuoka, Okayama (JP)

(73) Assignee: Panasonic Intellectual Property Management Co., Ltd., Osaka-shi, Osaka (JP)

(21) Appl. No.: 16/485,524

(22) PCT Filed: Dec. 26, 2017
(86) PCT No.: PCT/JP2017/046628

§ 371 Date: Aug. 13, 2019

(30) Foreign Application Priority Data
Feb. 15, 2017 (JP) 2017-026103

(51) Int. Cl. H01H 13/64; H03K 17/975; G01L 1/14; G01L 9/00; G06F 3/02; G06F 3/0338

(52) U.S. Cl. CPC H01H 13/64; H03K 17/975; G01L 1/148; H01H 2215/004; G06F 3/0202; G06F 3/0338; G01L 9/0072

(57) ABSTRACT

The determination system includes; an obtaining unit configured to obtain changes in electrostatic capacitances of the first and second pressure sensors from the input device; and a determining unit configured to determine which part of the input device has been pressed, based on a balance between changes in electrostatic capacitances of the first and second pressure sensors.

### TECHNICAL FIELD

The present disclosure generally relates to determination systems, determination methods, and determination programs and particularly relates to a determination system, a determination method, and a determination program for determining input to an input device based on output from the input device.

### BACKGROUND ART

Hereinafter, a conventional input device is described. The conventional input device includes a pressure sensor and an elastic member. The pressure sensor is disposed inside the elastic member. An inputter can cause elastic deformation of the elastic member by, for example, twisting or pulling it. The conventional input device detects this elastic deformation by the pressure sensor and outputs an input signal based on the pressure sensor.

Note that, this kind of input device is known from Patent Literature 1, for example.

However, the conventional input device can detect complex dynamic variations occurring inside the elastic member but cannot produce a click.

An object of the present disclosure would be to propose a determination system, a determination method, and a determination program which are capable of determining which part has been pressed in a pressure sensor equipped input device capable of producing a click when pressed.

### CITATION LIST

### Patent Literature

Patent Literature 1: JP 2012-004129 A

### SUMMARY OF INVENTION

A determination system of one aspect according to the present disclosure is a system for determining, based on output from an input device, input to the input device. The input device includes a metal dome and a plurality of pressure sensors which are electrostatic pressure sensors and placed facing a concave surface of the metal dome. The plurality of pressure sensors include a first and second pressure sensors which are on opposite sides, in a predetermined direction crossing a central axis of the metal dome, with respect to the center axis and which support the metal dome. The determination system includes; an obtaining unit configured to obtain changes in electrostatic capacitances of the first and second pressure sensors from the input device; and a determining unit configured to determine which part of the metal dome in the predetermined direction has been pressed, based on a balance between changes in electrostatic capacitances of the first and second pressure sensors.

A determination method of one aspect according to the present disclosure is a method for determining, based on output from an input device, input to the input device. The input device includes a metal dome and a plurality of pressure sensors which are electrostatic pressure sensors and placed facing a concave surface of the metal dome. The plurality of pressure sensors include a first and second pressure sensors which are on opposite sides, in a predetermined direction crossing a central axis of the metal dome, with respect to the center axis and which support the metal dome. The determination method includes; obtaining changes in electrostatic capacitances of the first and second pressure sensors from the input device; and determining which part of the metal dome in the predetermined direction has been pressed, based on a balance between changes in electrostatic capacitances of the first and second pressure sensors.

A determination program of one aspect according to the present disclosure is a program for enabling one or more processors to execute the above determination method.

### BRIEF DESCRIPTION OF DRAWINGS

FIG. 1 is a schematic diagram of an input system including an input device of Embodiment 1.

FIG. 2 is a perspective view of the input device.

FIG. 3 is an explanatory view of an operation of the input device with a metal dome being not pressed.

FIG. 4 is an explanatory view of an operation of the input device with the metal dome being pressed.

FIG. 5 is an exploded perspective view of the input device.

FIG. 6 is a partially enlarged view of the input device with the metal dome being not pressed.

FIG. 7 is a partially enlarged view of the input device with the metal dome being pressed.

FIG. 8 is a plan of the input device.

FIG. 9 is a graph representing a relation between amount of pressing (stroke) of the metal dome and load on the metal dome as well as electrostatic capacitances of the pressure sensors in relation to the input device.

FIG. 10 is another graph representing a relation between amount of pressing (stroke) of the metal dome and load on the metal dome as well as electrostatic capacitances of the pressure sensors in relation to the input device.

FIG. 11 is an equivalent circuit diagram of the input device in relation to measurement of an electrostatic capacitance of a first pressure sensor.

FIG. 12 is a circuit diagram of a more simplified equivalent circuit diagram of FIG. 11.

FIG. 13 is an equivalent circuit diagram of the input device in relation to measurement of an electrostatic capacitance of a second pressure sensor.

FIG. 14 is a circuit diagram of a more simplified equivalent circuit diagram of FIG. 13.

FIG. 15 is a flow chart of a first determination operation of a determination system of the input system.

FIG. 16 is a flow chart of a second determination operation of the determination system.

FIG. 17 is a schematic diagram of an input system according to Embodiment 2.

FIG. 18 is a perspective view of an input device of the input system.

FIG. 19 is a plan of the input device.

FIG. 20 is a schematic diagram of an input system according to Embodiment 3.

FIG. 21 is a perspective view of au input device of an input system according to Embodiment 4.

FIG. 22 is a perspective view of the input device.

FIG. 23 is a plan of a printed substrate of the input device.

FIG. 24 is a plan of the input device.

FIG. 25 is a section taken along the line A-A in FIG. 24.

FIG. 26 is an enlarged view of the region B in FIG. 25.

FIG. 27 is an explanatory view of an operation of the input device with a metal dome being not pressed.

FIG. 28 is an explanatory view of an operation of the input device with the metal dome being pressed.

FIG. 29 is a plan of a variation of a set of electrodes of the input device of the input system according to Embodiment 1.

FIG. 30 is a plan of a variation of a set of electrodes of the input device of the input system according to Embodiment 2.

### DESCRIPTION OF EMBODIMENTS

### 1. Embodiments

### 1.1 Embodiment 1

### 1.1.1 Outline

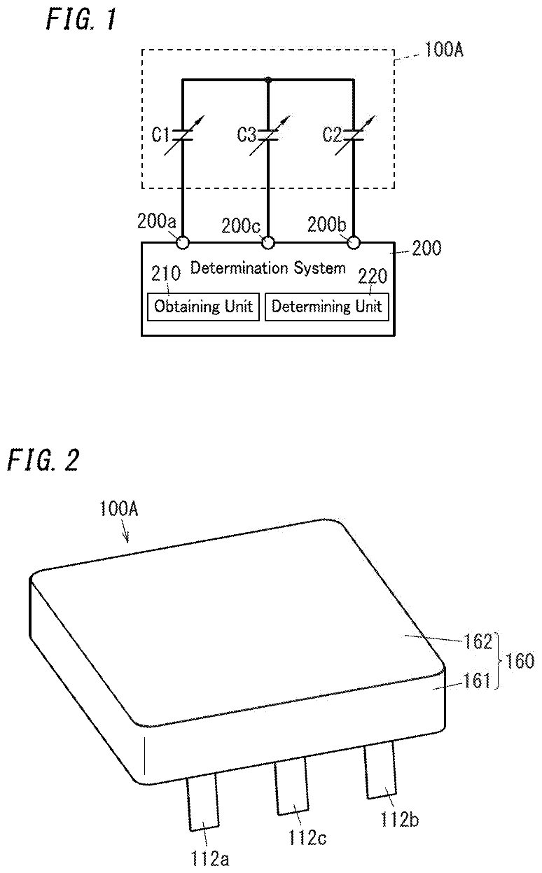

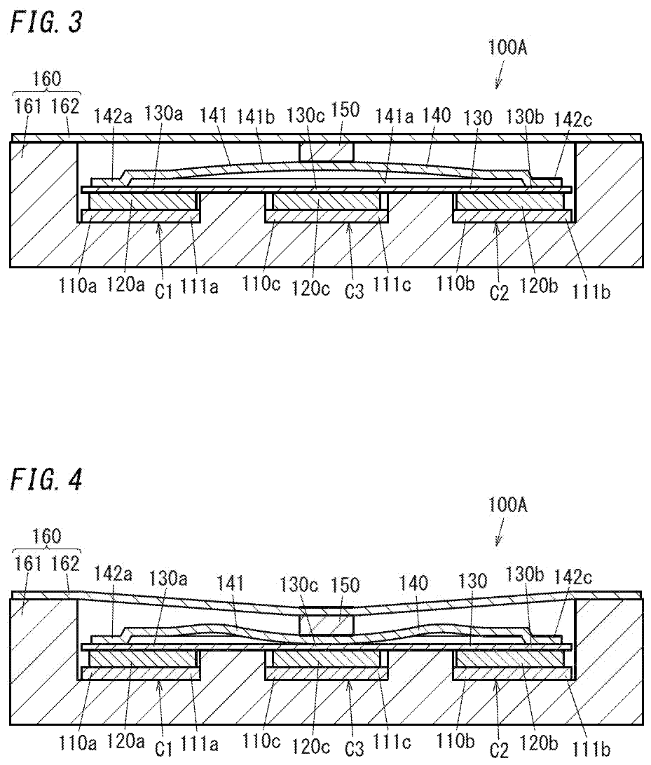

FIG. 1 is an illustration of an input system of the present embodiment. The input system includes an input device 100A and a determination system 200. FIG. 2 is an illustration of the input device 100A. The input device 100A includes, as shown in FIG. 3 and FIG. 4, a metal dome 140, and first, second, and third pressure sensors C1, C2, and C3. The first and second pressure sensors C1 and C2 face a concave surface 141a of the metal dome 140 and support the metal dome 140. Therefore, even before the metal dome 140 is elastically deformed and then a click is produced, pressing force applied on the metal dome 140 (pressing force applied on a convex surface 141b of the metal dome 140) can be measured by the first and second pressure sensors C1 and C2. After the metal dome 140 is elastically deformed and then a click is produced, pressing force applied on the metal dome 140 can be measured by the first to third pressure sensors C1 to C3. To sum up, irrespective of production of a click (irrespective of occurrence of elastic deformation of the metal dome 140), pressing force on the metal dome 140 can be measured.

### 1.1.2 Input Device

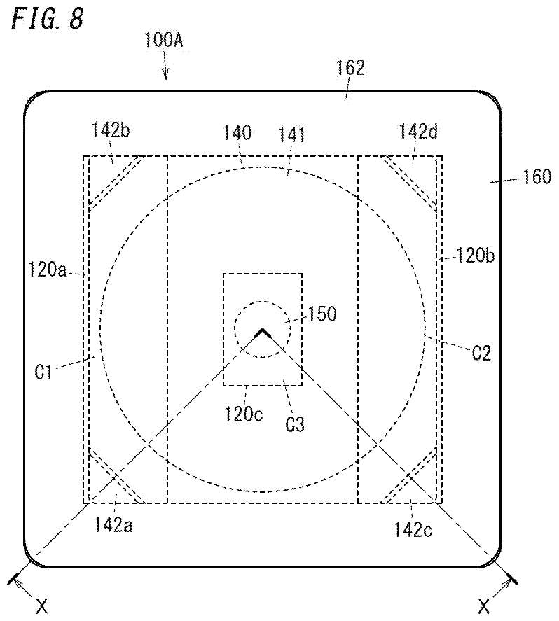

Hereinafter, the input device 100A is described in more detail with reference to FIG. 1 to FIG. 8. Note that, FIG. 3 corresponds to a section taken along line X-X in FIG. 8.

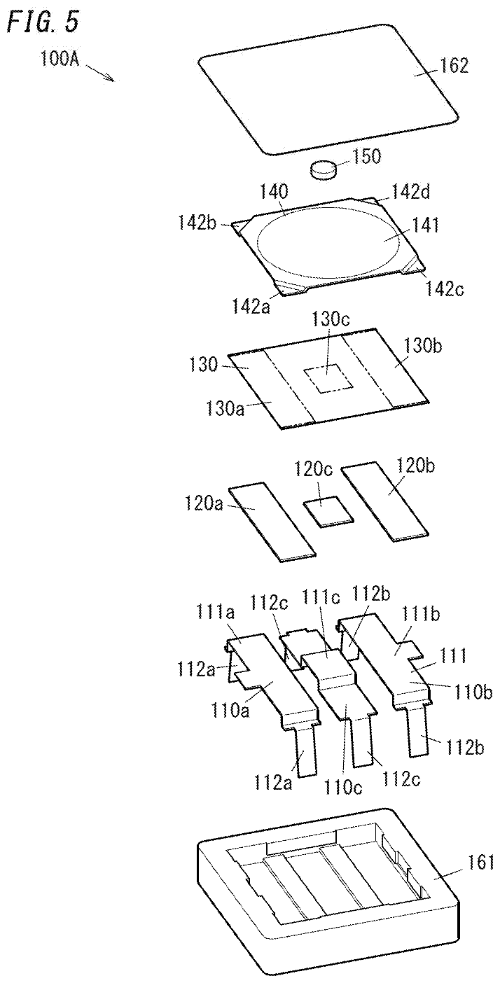

As shown in FIG. 5, the input device 100A includes first to third electrically conductive members 110a, 110b, and 110c, first to third elastic members 120a, 120b, and 120c, an insulating sheet 130, the metal dome 140, and a pressing member 150. Further, the input device 100A includes a housing 160 (see FIG. 2 to FIG. 4).

As shown in FIG. 3 and FIG. 4, the housing 160 accommodates the first to third electrically conductive members 110a, 110b, and 110c, the first to third elastic members 120a, 120b, and 120c, the insulating sheet 130, the metal dome 140, and the pressing member 150. The housing 160 includes a body 161 and a cover 162. The body 161 has a flat quadrangle (e.g., square) box shape and also has an opening in a first surface in a thickness axis thereof (an upper surface in FIG. 3 and FIG. 4). The cover 162 has a flat quadrangle (e.g., square) plate shape. The cover 162 is attached to the first surface of the body 161 to cover the opening in the first surface of the body 161. The body 161 and the cover 162 have electrically insulating properties. For example, the body 161 and the cover 162 are made of resin material with electrically insulating properties. Especially, the cover 162 has flexibility. Hence, it is possible to push or press the metal dome 140 accommodated in the housing 160 through the cover 162. An opposite surface of the cover 162 from the metal dome 140 provides an operation area of the input device 100A.

As shown in FIG. 5, the first electrically conductive member 110a includes an electrode 111a and a pair of terminals 112a. The electrode 111a has a rectangular flat plate shape. The pair of terminals 112a protrude from opposite ends in a length axis of the electrode 111a. Directions in which the pair of terminals 112a protrude from the electrode 111a are directions crossing the length axis and a width axis, of the electrode 111a. The second electrically conductive member 110b includes an electrode 111b and a pair of terminals 112b. The electrode 111b has a rectangular flat plate shape. The pair of terminals 112b protrude from opposite ends in a length axis of the electrode 111b. Directions in which the pair of terminals 112b protrude from the electrode 111b are directions crossing the length axis and a width axis, of the electrode 111b. The third electrically conductive member 110c includes an electrode 111c and a pair of terminals 112c. The electrode 111c has a rectangular flat plate shape. In this regard, the electrode 111c has a central part in a length axis thereof which protrudes in a thickness axis thereof from opposite ends thereof. The pair of terminals 112c protrude from opposite ends in the length axis of the electrode 111c. Directions in which the pair of terminals 112c protrude from the electrode 111c are directions crossing the length axis and a width axis, of the electrode 111c. The first to third electrically conductive members 110a, 110b, and 110c may be made of metal plates.

As shown in FIG. 3 and FIG. 4, the first to third electrically conductive members 110a to 110c are embedded in the body 161 by insert molding. Regarding the first electrically conductive member 110a, the electrode 111a is exposed on a bottom surface of the body 161 and the pair of terminals 112a protrude from a second surface in the thickness axis of the body 161 (a lower surface in FIG. 3 and FIG. 4). Regarding the second electrically conductive member 110b, the electrode 111b is exposed on the bottom surface of the body 161 and the pair of terminals 112b protrude from the second surface in the thickness axis of the body 161. Regarding the third electrically conductive member 110c, the central part in the thickness axis of the electrode 111c is exposed on the bottom surface of the body 161 and the pair of terminals 112c protrude from the second surface in the thickness axis of the body 161.

As shown in FIG. 5, the first elastic member 120a has a rectangular flat plate shape. The first elastic member 120a has an outer shape that is almost identical to an outer shape of the electrode 111a of the first electrically conductive member 110a. The first elastic member 120a is placed on the electrode 111a. The second elastic member 120b has a rectangular flat plate shape. The second elastic member 120b has an outer shape that is almost identical to an outer shape of the electrode 111b of the second electrically conductive member 110b. The second elastic member 120b is placed on the electrode 111b. The third elastic member 120c has a rectangular flat plate shape. The third elastic member 120c has an outer shape that is almost identical to an outer shape of the central part in the length axis of the electrode 111c of the third electrically conductive member 110c. The third elastic member 120c is placed on the central part in the length axis of the electrode 111c. In the present embodiment, the first to third elastic members 120a to 120c each have electrically conductive properties.

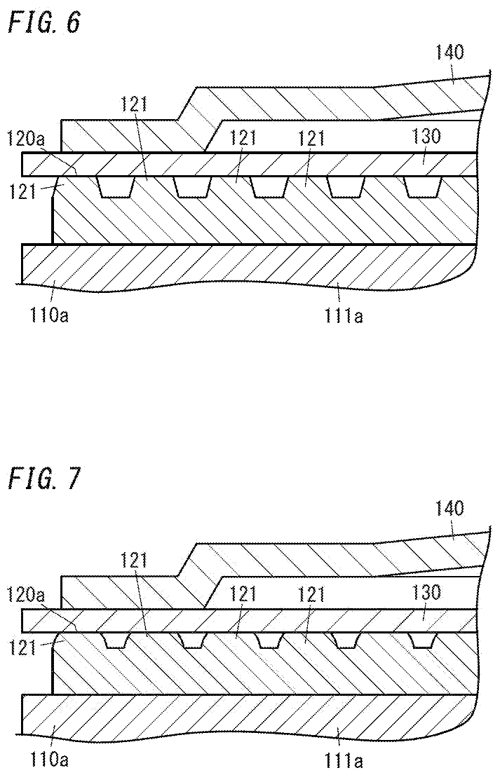

In addition, a first surface in a thickness axis of the first elastic member 120a includes a rough surface and a second surface in the thickness axis of the first elastic member 120a includes a flat surface. In one example, as shown in FIG. 6 and FIG. 7, the first surface in the thickness axis of the first elastic member 120a includes a plurality of protrusions 121. Similarly, a first surface in a thickness axis of each of the second and third elastic members 120b and 120c includes a rough surface and a second surface in the thickness axis of each of the second and third elastic members 120b and 120c includes a flat surface.

As shown in FIG. 5, the insulating sheet 130 is an insulator (dielectric member) with a quadrangle (e.g., square) sheet shape. The insulating sheet 130 has a size capable of covering the fit to third elastic members 120a, 120b, and 120c collectively. The insulating sheet 130 includes a first portion 130a for covering the first elastic member 120a, a second portion 130b for covering the second elastic member 120b, and a third portion 130c for covering the third elastic member 120c.

As shown in FIG. 5 and FIG. 8, the metal dome 140 has a quadrangle (e.g., square) plate shape as a whole. The metal dome 140 includes, at its center part, an elastically deformable part 141 with a dome shape. As shown in FIG. 3, a first surface in a thickness axis of the elastically deformable part 141 (a lower surface in FIG. 3) defines the concave surface 141a, and a second surface (an upper surface in FIG. 3) defines the convex surface 141b. As shown in FIG. 4, when the convex surface 141b of the elastically deformable part 141 is pressed, the elastically deformable part 141 is elastically deformed and thus a click is produced.

In more detail, such elastic deformation causes inversion of a central part of the elastically deformable part 141, and therefore the elastically deformable part 141 is charmed from a convex state to a concave state. Further, the metal dome 140 includes, at its individual four corners, legs (first to fourth legs) 142a to 142d. The first to fourth leas 142a to 142d protrude in directions opposite to a direction in which the elastically deformable part 141 protrudes. As shown in FIG. 8, the first and second legs 142a and 142b are placed on the first elastic member 120a. The third and fourth legs 142c and 142d are placed on the second elastic member 120b.

The pressing member 150 is a member for assisting causing elastic deformation of the elastically deformable part 141 of the metal dome 140. As shown in FIG. 5, the pressing member 150 has a circular disk shape. Further, the pressing member 150 has an outer shape smaller than an outer shape of the elastically deformable part 141 of the metal dome 140. As shown in FIG. 3, the pressing member 150 is placed between a central part of the convex surface 141b of the metal dome 140 and the cover 162. Especially, the pressing member 150 is fixed to the cover 162. Note that, the pressing member 150 has electrically insulating properties.

In the input device 100A, the first, second, and third electrically conductive members 110a, 110b and 110c, the first, second, and third elastic members 120a, 120b, and 120c, the insulating sheet 130, and the metal dome 140 serve as capacitors with electrostatic capacitances. In other words, the first, second, and third electrically conductive members 110a, 110b, and 110c, the first, second, and third elastic members 120a, 120b, and 120c, the insulating sheet 130, and the metal dome 140 constitute the first, second, and third pressure sensors C1, C2, and C3. In FIG. 1, the input device 100A is illustrated as an equivalent circuit. The first, second and third pressure sensors C1, C2, and C3 include the metal dome 140 as a common electrode and thus are electrically coupled with each other.

In more detail, as shown in FIG. 3 and FIG. 4, the first pressure sensor C1 is constituted by the electrode 111a of the first electrically conductive member 110a, the first elastic member 120a, the first portion 130a of the insulating sheet 130, and the first and second legs 142a and 142b of the metal dome 140. In other words, the first pressure sensor C1 is constituted by the electrode 111a, a predetermined part (the first and second legs 142a and 142b) of the metal dome 140 supported on the electrode 111a, and an insulator (the first portion 130a) between the electrode 111a and the predetermined part. Additionally, the first pressure sensor C1 includes an elastic member (the first elastic member 120a) between the insulator (the first portion 130a) and the electrode 111a. In this regard, the first elastic member 120a includes the plurality of protrusions 121. Therefore, as shown in FIG. 7, the plurality of protrusions 121 are crushed when the first elastic member 120a is pressed by the metal dome 140. Thus, the first elastic member 120a is thinned as a whole and simultaneously a contact area between the first elastic member 120a and the insulating sheet 130 is increased. Therefore, a linearity of change in electrostatic capacitance to pressing force on the first pressure sensor C1 is improved in contrast to a case where only the thickness of the first elastic member 120a is changed. Note that, the aforementioned predetermined part (parts of the first and second legs 142a and 142b in contact with the insulating sheet 130) resting on the insulating sheet 130 may preferably include one or more predetermined flat surface regions. According to this configuration, the one or more flat surface regions are placed near and opposite the electrode 111a. The one or more flat surface regions assist the metal dome 140 to press a greater number of protrusions 121. Thus, change in electrostatic capacitance can be increased. In the present embodiment, entire surfaces of the first and second legs 142a and 142b facing the insulating sheet 130 are flat surface regions.

As shown in FIG. 3 and FIG. 4, the second pressure sensor C2 is constituted by the electrode 111b of the second electrically conductive member 110b, the second elastic member 120b, the second portion 130b of the insulating sheet 130, and the third and fourth legs 142c and 142d of the metal dome 140. In other words, the second pressure sensor C2 is constituted by the electrode 111b, a predetermined part (the third and fourth legs 142c and 142d) of the metal dome 140 supported on the electrode 111b, and an insulator (the second portion 130b) between the electrode 111b and the predetermined part. Additionally, the second pressure sensor C2 includes an elastic member (the second elastic member 120b) between the insulator (the second portion 130b) and the electrode 111b. In this regard, the second elastic member 120b includes the plurality of protrusions 121 in a similar manner to the first elastic member 120a. Therefore, a linearity of change in electrostatic capacitance to pressing force on the second pressure sensor C2 is improved. Similarly to the aforementioned situation, parts of the third and fourth legs 142c and 142d in contact with the insulating sheet 130 may preferably include one or more predetermined flat surface regions. In the present embodiment, entire surfaces of the third and fourth legs 142c and 142d facing the insulating sheet 130 are flat surface regions.

Each of the first pressure sensor C1 and the second pressure sensor C2 is a pressure sensor facing the concave surface 141a of the metal dome 140 and supporting the metal dome 140. The first pressure sensor C1 and the second pressure sensor C2 are on opposite sides, in a predetermined direction crossing the central axis of the metal dome 140, with respect to the center axis. In the present embodiment, the predetermined direction is a direction perpendicular to the central axis of the metal dome 140 and also a direction in which the first leg 142a and the third leg 142c (or the second leg 142b and the fourth leg 142d) are arranged. In summary, in FIG. 8, the predetermined direction is parallel to left and right directions. Further, each of the first pressure sensor C1 and the second pressure sensor C2 is an electrostatic pressure sensor.

The third pressure sensor C3 is constituted by the electrode 111c of the third electrically conductive member 110c, the third elastic member 120c, the third portion 130c of the insulating sheet 130, and the elastically deformable part 141 of the metal dome 140. The third pressure sensor C3 further includes an elastic member (the third elastic member 120c) between an insulator (the third portion 130c of the insulating sheet 130) and the electrode 111c. In this regard, similarly to the first elastic member 120a, the third elastic member 120c includes a plurality of protrusions. Therefore, a linearity of change in electrostatic capacitance to pressing force on the third pressure sensor C3 is improved.

The third pressure sensor C3 is an electrostatic pressure sensor analogous to the first and second pressure sensors C1 and C2. However, as shown in FIG. 3, the third pressure sensor C3 is different from the first and second pressure sensors C1 and C2 and is not a pressure sensor facing the concave surface 141a of the metal dome 140 and supporting the metal dome 140. The third pressure sensor C3 is placed facing the concave surface 141a of the metal dome 140 but is spaced apart from the metal dome 140. The third pressure sensor C3 is placed facing the concave surface 141a of the metal dome 140 and functions as a detector for detecting elastic deformation of the metal dome 140 (the elastically deformable part 141) caused by pressing the convex surface 141b of the metal dome 140.

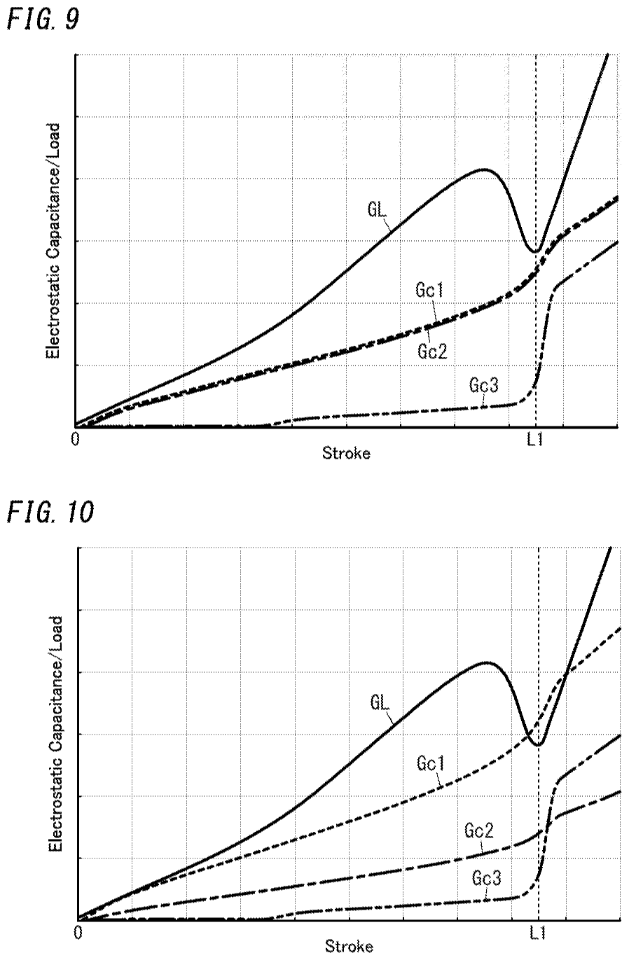

FIG. 9 and FIG. 10 relate to the input device 100A and show relations between amount of pressing (stroke) of the metal dome 140 and load (pressing force) on the metal dome 140 as well as electrostatic capacitances of the pressure sensors C1 to C3.

A graph shown in FIG. 9 corresponds to a situation where the central part in the predetermined direction of the metal dome 140 (part corresponding to the third pressure sensor C3) is pressed. In FIG. 9, Gc1 denotes an electrostatic capacitance of the first pressure sensor C1, Gc2 denotes an electrostatic capacitance of the second pressure sensor C2, and Gc3 denotes an electrostatic capacitance of the third pressure sensor C3. Additionally, GL denotes load on the metal dome 140.

The first and second pressure sensors C1 and C2 supports the metal dome 140 and are on opposite sides of the metal dome 140, in the predetermined direction crossing the central axis of the metal dome 140, with respect to the center axis. Therefore, when the central part of the metal dome 140 is pressed, almost equal pressures act on the first and second pressure sensors C1 and C2. Hence, electrostatic capacitances of the first and second pressure sensors C1 and C2 are increased with increase in amount of pressing (stroke) of the metal dome 140. On the other hand, the third pressure sensor C3 does not support the metal dome 140 and therefore sees change in its electrostatic capacitance smaller than those of the first and second pressure sensors C1 and C2. When amount of pressing (stroke) of the metal dome 140 increases and reaches a prescribed value L1, the elastically deformable part 141 of the metal dome 140 is elastically deformed and then a click is produced. As shown in FIG. 4, the elastically deformable part 141 of the metal dome 140 comes into contact with the third portion 130c when elastically deformed. In summary, elastic deformation of the elastically deformable part 141 causes a large change in a distance between the central part of the elastically deformable part 141 and the electrode 111c. Such a large change in that distance may cause a large change in electrostatic capacitance of the third pressure sensor C3.

A graph shown in FIG. 10 corresponds to a situation where a first end in the predetermined direction of the metal dome 140 (left part in FIG. 8, i.e., part corresponding to the first pressure sensor C1) is pressed. Also in FIG. 10, Gc1 denotes electrostatic capacitance of the first pressure sensor C1, Gc2 denotes electrostatic capacitance of the second pressure sensor C2, and Gc3 denotes electrostatic capacitance of the third pressure sensor C3. Additionally, GL denotes the load on the metal dome 140.

As described above, the first and second pressure sensors C1 and C2 supports the metal dome 140 and are on opposite sides of the metal dome 140, in the predetermined direction crossing the central axis of the metal dome 140, with respect to the center axis. Therefore, when the part of the metal dome 140 corresponding to the first pressure sensor C1 is pressed, the first pressure sensor C1 sees pressure higher than that acting on the second pressure sensor C2. The electrostatic capacitances of the first and second pressure sensors C1 and C2 are increased with increase in amount of pressing (stroke) of the metal dome 140. However, change in electrostatic capacitance of the first pressure sensor C1 becomes larger than change in electrostatic capacitance of the second pressure sensor C2. In contrast, when a second end in the predetermined direction of the metal dome 140 (right part in FIG. 8, i.e., part corresponding to the second pressure sensor C2) is pressed, change in electrostatic capacitance of the second pressure sensor C2 becomes larger than change in electrostatic capacitance of the first pressure sensor C1. Accordingly, the input device 100A can identify which part of the metal dome 140 has been pressed by an inputter, in the predetermined direction crossing the central axis of the metal dome 140.

Each of the first third pressure sensors C1 to C3 is an electrostatic pressure sensor and therefore can be used as a proximity sensor for sensing an object with the ground potential (e.g., fingers or hands of an inputter). This utilizes pseudo capacitors formed between an object with the ground potential and the pressure sensors (C1 to C3). In one example, the input device 100A can detect fingers or hands of an inputter close to the metal dome 140 by the first to third pressure sensors C1 to C3.

### 1.1.3 Determination System

The determination system 200 is configured to determine input to the input device 100A based on output (an input result) from the input device 100A. In the present embodiment, the input result includes values of (changes in) electrostatic capacitances of the first to third pressure sensors C1 and C3 of the input device 100A.

As shown in FIG. 1, the determination system 200 includes first to third terminals 200a to 200c. The first to third terminals 200a to 200c are electrically connected to the first to third pressure sensors C1 to C3 of the input device 100A, respectively. For example, the first, second and third terminals 200a, 200b, and 200c are connected to one terminal 112a of the first electrically conductive member 110a, one terminal 112b of the second electrically conductive member 110b, and one terminal 112c of the third electrically conductive member 110c. By doing so, the determination system 200 is electrically connected to the first, second and third pressure sensors C1, C2, and C3 (the electrodes 111a, 111b, and 111c).

As shown in FIG. 1, the determination system 200 includes an obtaining unit 210 and a determining unit 220.

The obtaining unit 210 is configured to obtain changes in electrostatic capacitances of the first and second pressure sensors C1 and C2 from the input device 100A. Further, the obtaining unit 210 is configured to obtain change in electrostatic capacitance of the third pressure sensor C3 from the input device 100A. The obtaining unit 210 can switch sensitivity for obtaining changes in electrostatic capacitances of the plurality of pressure sensors C1 to C3 from the input device 100A, between a first level and a second level higher than the first level.

The method for Obtaining electrostatic capacitances of pressure sensors (C1, C2, C3) may be selected from conventional various methods. In one example, a switched capacitor method may apply. The switched capacitor method measures (changes in) electrostatic capacitances of pressure sensors, based on amounts of electric charges stored in capacitors constituting the pressure sensors. For example, the obtaining unit 210 repeats alternately a charging process of charging a pressure sensor (capacitor) and a discharging process of charging a determination capacitor with electric charges stored in the pressure sensor by making the pressure sensor discharge, for a predetermined period of time. When a voltage across the determination capacitor reaches a prescribed value, the obtaining unit 210 ends the discharging process and starts the charging process. Accordingly, the number of times that the voltage across the determination capacitor reaches the prescribed value within the predetermined period of time increases with increase in electrostatic capacitance of the pressure sensor. Therefore, change in electrostatic capacitance of the pressure sensor can be determined based on the number of times that the voltage across the determination capacitor reaches the prescribed value within the predetermined period of time. In this regard, increase in the prescribed value may cause decrease in the number of times that the voltage across the determination capacitor reaches the prescribed value within the predetermined period of time. In contrast, decrease in the prescribed value may cause increase in the number of times that the voltage across the determination capacitor reaches the prescribed value within the predetermined period of time. Thus, the prescribed value can be used for adjustment of the sensitivity. Note that, the sensitivity can be adjusted based on a voltage applied across the pressure sensor in the charging process. Alternatively, the sensitivity can be adjusted based on time necessary for charging and/or discharging, for example, time necessary for the determination capacitor to be charged up.

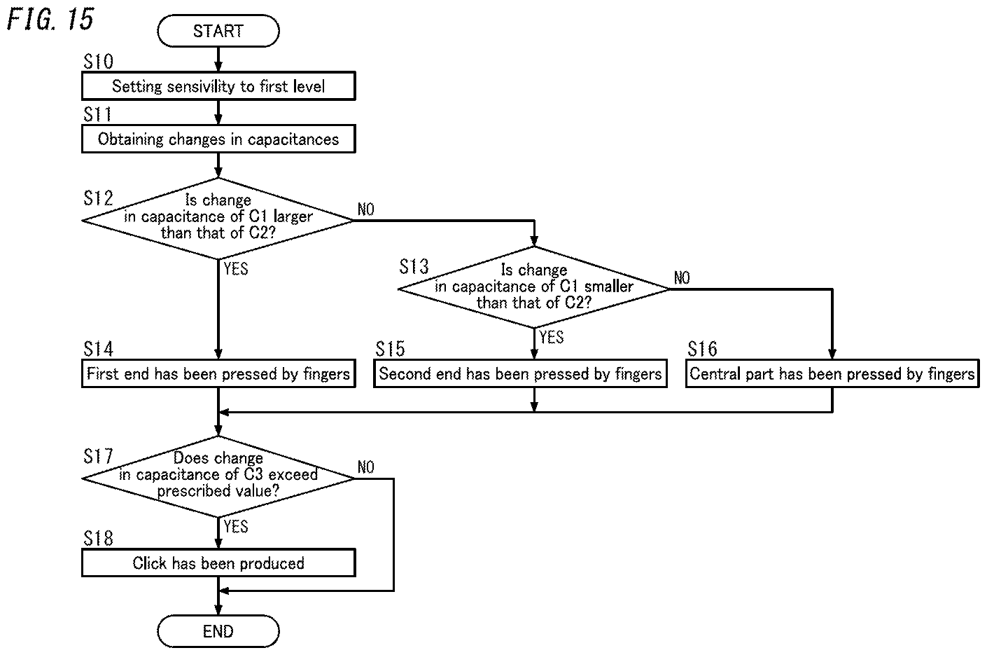

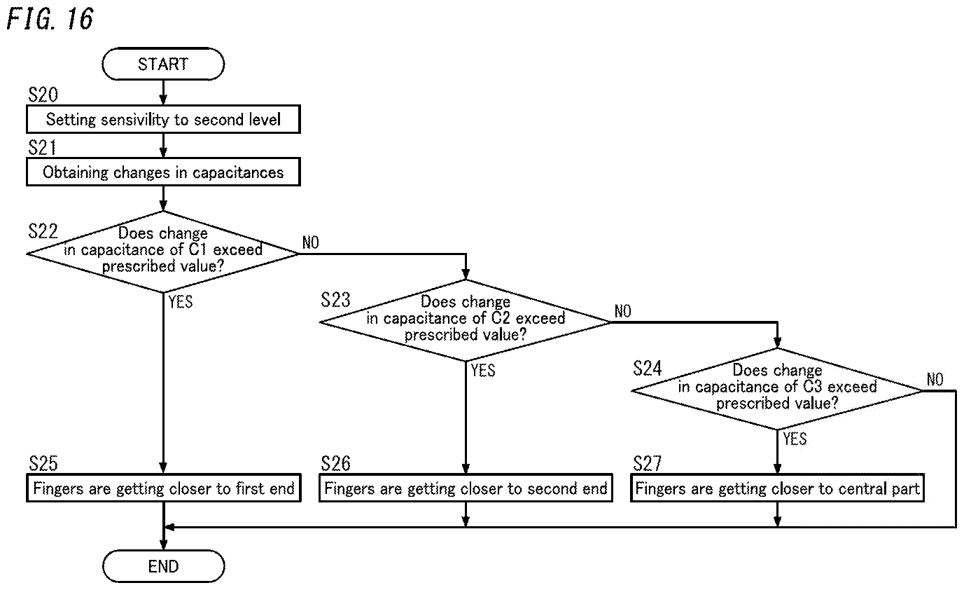

The determining unit 220 is configured to determine which part of the metal dome 140 in the predetermined direction has been pressed (inclination), based on a balance between changes in electrostatic capacitances of the first and second pressure sensors C1 and C2. The balance between changes in electrostatic capacitances of the first and second pressure sensors C1 and C2 can be evaluated based on a relation between amounts of changes in electrostatic capacitances of the first and second pressure sensors C1 and C2. Additionally, the determining unit 220 is configured to determine whether the metal dome 140 has been elastically deformed (a click has been produced), based on change in electrostatic capacitance of the third pressure sensor C3. Further, the determining unit 220 is configured to determine whether a detection target (e.g., fingers of an inputter) is present near the metal dome 140, based on changes in electrostatic capacitances of the plurality of pressure sensors C1 to C3. A detailed operation of the determining unit 220 is described later with reference to flow charts shown in FIG. 15 and FIG. 16.

The determination system 200 is configured to perform a first determination operation and a second determination operation by the obtaining unit 210 and the determining unit 220. The first determination operation is defined as an operation of performing determination of an inclination of the metal dome 140 and determination as to whether elastic deformation of the metal dome 140 has occurred. In other words, the first determination operation may be an operation of measuring amount of pressing of the metal dome 140 and detecting production of the click. The second determination operation is defined as an operation of determining whether a detection target (an object with a around potential) is in a vicinity of the metal dome 140. Hereinafter, the first and second determination operations of the determination system 200 are described with reference to the flow charts illustrated in FIG. 15 and FIG. 16.

FIG. 15 shows the flow chart of the first determination operation. First of all, the obtaining unit 210 sets the sensitivity for measuring changes in electrostatic capacitances to the first level (S10).

Next, the obtaining unit 210 obtains the changes in electrostatic capacitances (S11). In detail, the obtaining unit 210 applies a voltage across one of the first to third terminals 200a to 200c and grounds the others. By doing so, the obtaining unit 210 measures changes in electrostatic capacitances of the first to third pressure sensors C1 to C3 in turn.

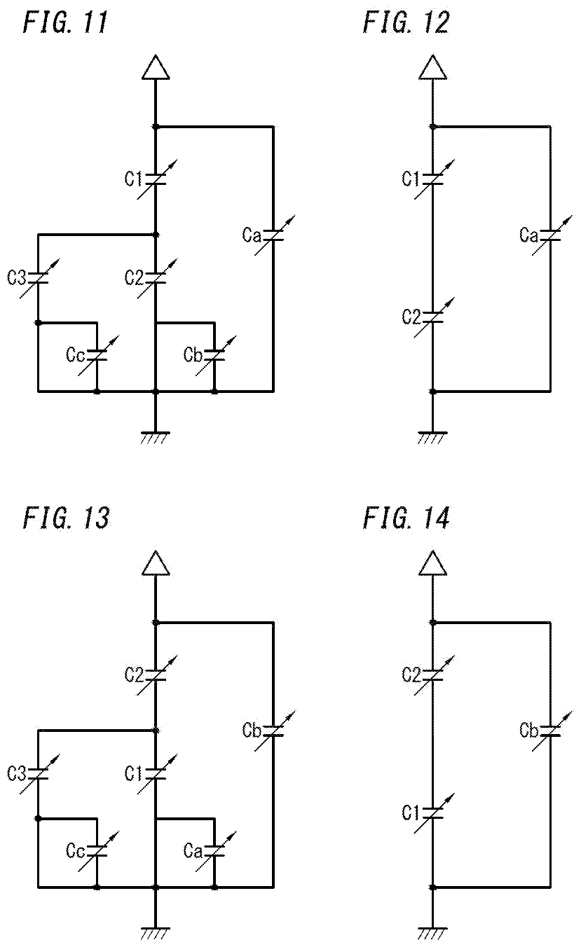

To measure change in electrostatic capacitance of the first pressure sensor C1, the obtaining unit 210 applies a voltage to the first terminal 200a and grounds the second and third terminals 200b and 200c. As a result, the first pressure sensor C1 is connected to a parallel circuit of the second and third pressure sensors C2 and C3. FIG. 11 shows an equivalent circuit diagram of the input system in this situation. Ca denotes parasitic capacitance produced between the electrode 111a of the first pressure sensor C1 and a ground near the input device 100A. Cb denotes parasitic capacitance produced between the electrode 111b of the second pressure senor C2 and aground near the input device 100A. Cc denotes parasitic capacitance produced between the electrode 111c of the third pressure sensor C3 and a ground near the input device 100A. When the second and third pressure sensors C2 and C3 are grounded, effects of parasitic capacitances Cb and Cc can be ignored. Additionally, before a click is produced, the third pressure sensor C3 can be ignored. Therefore, the equivalent circuit diagram of FIG. 11 can be simplified as shown in FIG. 12. The obtaining unit 210 obtains, as change in electrostatic capacitance of the first pressure sensor C1, change in electrostatic capacitance of a parallel circuit of parasitic capacitance Ca and a series circuit of the first and second pressure sensors C1 and C2.

To measure change in electrostatic capacitance of the second pressure sensor C2, the obtaining unit 210 applies a voltage to the second terminal 200b and grounds the first and third terminals 200a and 200c. As a result, the second pressure sensor C2 is connected to a parallel circuit of the first and third pressure sensors C1 and C3. FIG. 13 shows an equivalent circuit diagram of the input system in this situation. When the first and third pressure sensors C1 and C3 are grounded, effects of parasitic capacitances Ca and Cc can be ignored. Additionally, before a click is produced, the third pressure sensor C3 can be ignored. Therefore, the equivalent circuit diagram of FIG. 13 can be simplified as shown in FIG. 14. The obtaining unit 210 obtains, as change in electrostatic capacitance of the second pressure sensor C2, change in electrostatic capacitance of a parallel circuit of parasitic capacitance Cb and a series circuit of the first and second pressure sensors C1 and C2.

To measure change in electrostatic capacitance of the third pressure sensor C3, the obtaining unit 210 applies a voltage to the third terminal 200c and grounds the first and second terminals 200a and 200b. As a result, the third pressure sensor C3 is connected to a parallel circuit of the first and second pressure sensors C1 and C2. The obtaining unit 210 obtains, as change in electrostatic capacitance of the third pressure sensor C3, change in electrostatic capacitance of a series circuit of the third pressure sensor C3 and a parallel circuit of the first and second pressure sensors C1 and C2.

Changes in electrostatic capacitances of the first to third pressure sensors C1 to C3 are obtained in step S11 and then the determining unit 220 determines which part of the metal dome 140 in the predetermined direction has been pressed (inclination), based on a balance of changes in electrostatic capacitances of the first and second pressure sensors C1 and C2. First, the determining unit 220 compares changes in electrostatic capacitances of the first and second pressure sensors C1 and C2 (S12, S13). Note that, before comparison between changes in electrostatic capacitances of the first and second pressure sensors C1 and C2, the determining unit 220 may perform processing of adjusting magnitudes or amounts of changes in electrostatic capacitances of the first and second pressure sensors C1 and C2 to allow appropriate comparison therebetween. Based on a result of the comparison between changes in electrostatic capacitances of the first and second pressure sensors C1 and C2, the determining unit 220 determines which part of the metal dome 140 in the predetermined direction has been pressed. If change in electrostatic capacitance of the first pressure sensor C1 is larger than change in electrostatic capacitance of the second pressure sensor C2 (S12; YES), the determining unit 220 determines that the first end of the metal dome 140 (the left part thereof in FIG. 8) has been pressed (S14). If change in electrostatic capacitance of the second pressure sensor C2 is larger than change in electrostatic capacitance of the first pressure sensor C1 (S12; NO, S13; YES), the determining unit 220 determines that the second end of the metal dome 140 (the right part thereof in FIG. 8) has been pressed (S15). If change in electrostatic capacitance of the first pressure sensor C1 is equal to change in electrostatic capacitance of the second pressure sensor C1 (S12; NO, S13; NO), the determining unit 220 determines that the central part of the metal dome 140 (the center thereof in FIG. 8) has been pressed (S16). Additionally, based on the balance between changes in electrostatic capacitances of the first and second pressure sensors C1 and C2, the determining unit 220 may determine a degree of pressing (amount of pressing) in addition to pressed part of the metal dome 140 in the predetermined direction. For example, it is considered that amount of pressing increases with increase in changes in electrostatic capacitances of pressure sensors. Therefore, the determining unit 220 may determine amount of pressing in accordance with changes in electrostatic capacitances of pressure sensors (C1, C2).

After steps S14, S15, and S16, the determining unit 220 determines whether the metal dome 140 has been elastically deformed (a click has been produced), based on change in electrostatic capacitance of the third pressure sensor C3. In detail, the determining unit 220 determines whether change in electrostatic capacitance of the third pressure sensor C3 exceeds a prescribed value (S17). This prescribed value defines a threshold value for determining whether the elastically deformable part 141 of the metal dome 140 has been elastically deformed to produce a click. If change in electrostatic capacitance of the third pressure sensor C3 exceeds the prescribed value (S17; YES), the determining unit 220 determines that a click has been produced (S18).

FIG. 16 shows the low chart of the second determination operation. First of all, the obtaining unit 210 sets the sensitivity for measuring changes in electrostatic capacitances to the second level (S20). As described above, the second level is selected to be higher than the first level. In summary, the obtaining unit 210 makes the sensibility in the second determination operation larger than in the first determination operation. To measure changes in electrostatic capacitances of the first to third pressure sensors C1 to C3 caused by approaching of an object with a ground potential, the sensibility in the second determination operation is made to be larger than in the first determination operation for measuring changes in electrostatic capacitances of the first to third pressure sensors C1 to C3 caused by pressing force. Therefore, it is possible to increase accuracy of determination as to whether a detection target is near the metal dome 140.

Next, the obtaining unit 210 obtains changes in electrostatic capacitances (S21). In detail, the obtaining unit 210 measures changes in electrostatic capacitances of the first to third pressure sensors C1 to C3 in the same manner as step S11.

After step S21, based on changes in electrostatic capacitances of the plurality of pressure sensors C1 to C3, the determining unit 220 determines whether the detection target (e.g., fingers of an inputter) is near the metal dome 140. In detail, the determining unit 220 determines whether changes in electrostatic capacitances of the first to third pressure sensors C1 to C3 exceed respective prescribed values (S22 to S24). If change in electrostatic capacitance of the first pressure sensor C1 exceeds the corresponding prescribed value (S22; YES), the determining unit 220 determines fingers of an inputter is in a vicinity of the first end of the metal dome 140 (the left part thereof in FIG. 8, part thereof corresponding to the first pressure sensor C1) (S25). If change in electrostatic capacitance of the second pressure sensor C2 exceeds the corresponding prescribed value (S23; YES), the determining unit 220 determines fingers of an inputter is in a vicinity of the second end of the metal dome 140 (the right part thereof in FIG. 8, part thereof corresponding to the second pressure sensor C2) (S26). If change in electrostatic capacitance of the third pressure sensor C3 exceeds the corresponding prescribed value (S24; YES), the determining unit 220 determines fingers of an inputter is in a vicinity of the central part of the metal dome 140 (the center thereof in FIG. 8, part thereof corresponding to the third pressure sensor C3) (S27). Note that, the prescribed values for the first to third pressure sensors C1 to C3 may be different or same. The second determination operation uses the first to third pressure sensors C1 to C3 which are also used in the first determination operation. Therefore, no additional sensors are required to determine whether a detection target is in a vicinity of the metal dome 140.

As described above, the determination system 200 is a determination system configured to determine input to the input device 100A based on output from the input device 100A, and includes the obtaining unit 210 and the determining unit 220. The obtaining unit 210 obtains changes in electrostatic capacitances of the first and second pressure sensors C1 and C2 from the input device 100A. The determining unit 220 determines which part of the metal dome 140 in the predetermined direction has been pressed (inclination), based on the balance between changes in electrostatic capacitances of the first and second pressure sensors C1 and C2. The determination system 200 may be implemented by one or more processors (microprocessors) and one or more memories, for example. In one example, the determination system 200 may be realized by a micro control unit. As described above, the one or more processors execute one or more programs stored in the one or more memories to function as the determination system 200. Stated differently, the one or more programs include a determination program allowing the one or more processors to perform the following determination method. The determination method includes obtaining changes in electrostatic capacitances of the first and second pressure sensors C1 and C2 from the input device 100A. Further, the determination method includes determining which part of the metal dome 140 in the predetermined direction has been pressed (inclination), based on the balance between changes in electrostatic capacitances of the first and second pressure sensors C1 and C2.

### 1.2 Embodiment 2

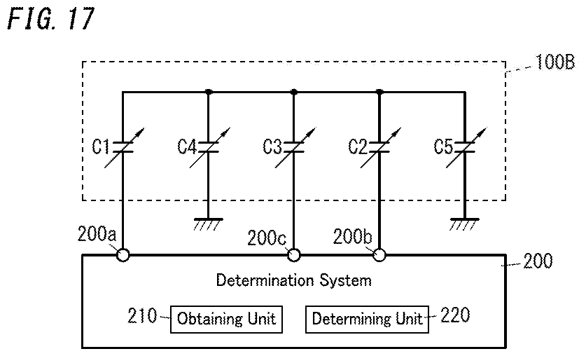

FIG. 17 is an illustration of an input system of the present embodiment. The input system includes an input device 100B and a determination system 200.

As shown in FIG. 17, the input device 100B includes fourth and fifth pressure sensors C4 and C5 in addition to the first to third pressure sensors C1 to C3.

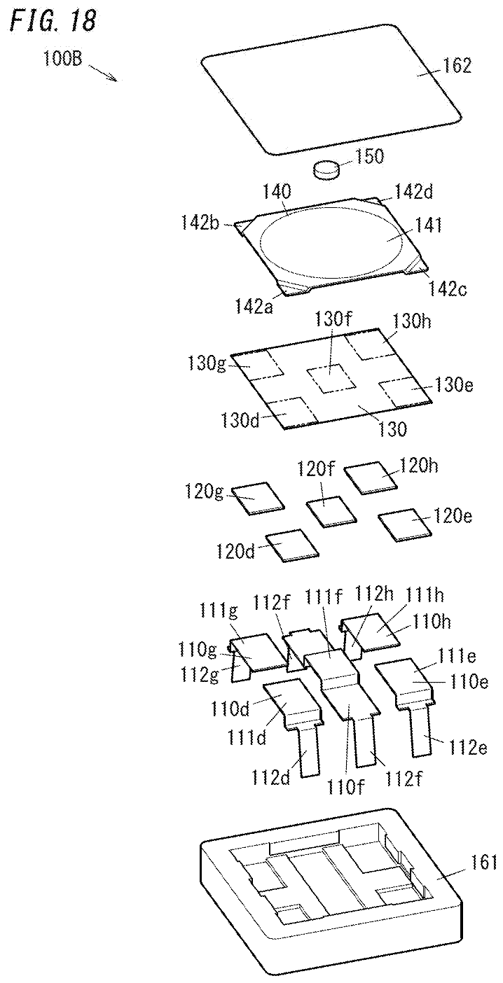

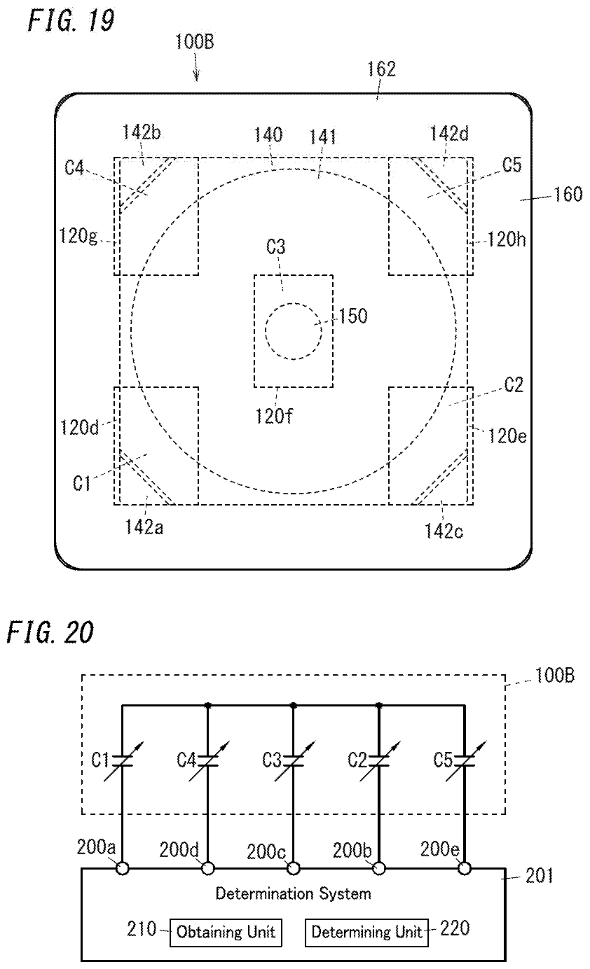

Hereinafter, the input device 100B is described in detail with reference to FIG. 18 and FIG. 19. As shown in 18, the input device 100B includes first to fifth electrically conductive members 110d to 110h, first to fifth elastic members 120d to 120h, the insulating sheet 130, the metal dome 140, and the pressing member 150. Additionally, the input device 100B includes the housing 160 (see FIG. 19).

As shown in FIG. 18, the first electrically conductive member 110d includes an electrode 111d and a terminal 112d. The electrode 111d has a rectangular flat plate shape. The terminal 112d protrudes from one end in a length axis of the electrode 111d. A direction in which the terminal 112d protrudes from the electrode 111d is a direction crossing the length axis and a width axis of the electrode 111d. The second, fourth and fifth electrically conductive members 110e, 110g, and 110h each have the same shape as the first electrically conductive member 110d and include electrodes 111e, 111g, and 111h and terminals 112e, 112g, and 112h, respectively. The third electrically conductive member 110f has the same shape as the third electrically conductive member 110c of the input device 100A and includes an electrode 111f and a pair of terminals 112f. The first to fifth electrically conductive members 110d to 110h may be made of metal plates.

The first to fifth electrically conductive members 110d to 110h are embedded in the body 161 by insert molding. In this regard, the electrodes 111d, 111e, 111g, and 111h of the first, second, fourth, and fifth electrically conductive members 110d, 110e, 110g, and 110h are exposed on four corners of the bottom surface of the body 161, respectively. In contrast, a central part of the electrode 111f of the third electrically conductive member 110f is exposed on a center of the bottom surface of the body 161. The terminals 112d, 112e, 112g, and 112h of the first, second, fourth, and fifth electrically conductive members 110d, 110e, 110g, and 110h and the pair of terminals 112f of the third electrically conductive member 110f protrude from the second surface in the thickness axis of the body 161.

As shown in FIG. 18, the first to fifth elastic members 120d to 120h each have a rectangular flat plate shape. The first, second, fourth, and fifth elastic members 120d, 120e, 120g, and 120h have outer shapes almost identical to outer shapes of corresponding electrodes 111d, 111e, 111g, and 111h, respectively. The first, second, fourth, and fifth elastic members 120d, 120e, 120g, and 120h are placed on corresponding electrodes 111d, 111e, 111g, and 111h, respectively. The third elastic member 120f has an cuter shape almost identical to an outer shape of a central part in a length axis of the electrode 111f of the third electrically conductive member 110f. The third elastic member 120f is placed on the central part in the length axis of the electrode 111f. In the present embodiment, the first to fifth elastic members 120d to 120h each are electrically conductive. Additionally, a first surface in a thickness axis of each of the first to fifth elastic members 120d to 120h includes a rough surface and a second surface in the thickness axis of each of the first to fifth elastic members 120d to 120h includes a flat surface. In one example, the first surface in the thickness axis of each of the first to fifth elastic members 120d to 120h includes a plurality of protrusions 121 (see FIG. 6 and FIG.) similarly to the first elastic member 120a of the input device 100A.

As shown in FIG. 18, the insulating sheet 130 has a size capable of covering the first to fifth elastic members 120d to 120h collectively. The insulating sheet 130 includes first to fifth portions 130d to 130h which cover the first to fifth elastic members 120d to 120h respectively.

The metal dome 140 includes at its four corners the first to fourth legs 142a to 142d similarly to Embodiment 1. As shown in FIG. 19, the first, second, third and fourth legs 142a, 142b, 142c, and 142d are placed on the first, second, third, and fifth elastic members 120d, 120e, 120g, and 1201h, respectively.

In the input device 100B, the first to fifth electrically conductive members 110d to 110h, the first to fifth elastic members 120d to 120h, the insulating sheet 130, and the metal dome 140 server as capacitors with electrostatic capacitances. Stated differently, the first to fifth electrically conductive members 110d to 110h, the first to fifth elastic members 120d to 120h the insulating sheet 130, and the metal dome 140 constitute first to fifth pressure sensors C1 to C5.

In more detail, the first pressure sensor C1 is constituted by the electrode 111d of the first electrically conductive member 110d, the first elastic member 120d, the first portion 130d of the insulating sheet 130, and the first leg 142a of the metal dome 140. In other words, the first pressure sensor C1 is constituted by the electrode 111d, a predetermined part (the first leg 142a) of the metal dome 140 supported on the electrode 111d, and an insulator (the first portion 130d) between the electrode 111d and the predetermined part. The first pressure sensor C1 further includes an elastic member (the first elastic member 120d) between the insulator (the first portion 130d) and the electrode 111d.

The second pressure sensor C2 is constituted by the electrode 111e of the second electrically conductive member 110e, the second elastic member 120e, the second portion 130e of the insulating sheet 130, and the third leg 142c of the metal dome 140. In other words, the second pressure sensor C2 is constituted by the electrode 111e, a predetermined part (the third leg 142c) of the metal dome 140 supported on the electrode 111e, and an insulator (the second portion 130e) between the electrode 111e and the predetermined part. The second pressure sensor C2 further includes an elastic member (the second elastic member 120e) between the insulator (the second portion 130e) and the electrode 111e.

The fourth pressure sensor C4 is constituted by the electrode 111g of the fourth electrically conductive member 110g, the fourth elastic member 120g, the fourth portion 130g of the insulating sheet 130, and the second leg 142b of the metal dome 140. In other words, the fourth pressure sensor C4 is constituted by the electrode 111g, a predetermined part (the second leg 142b) of the metal dome 140 supported on the electrode 111g, and an insulator (the fourth portion 130g) between the electrode 111g and the predetermined part. The fourth pressure sensor C4 further includes an elastic member (the fourth elastic member 120g) between the insulator (the fourth portion 130g) and the electrode 111g.

The fifth pressure sensor C5 is constituted by the electrode 111h of the fifth electrically conductive member 110h, the fifth elastic member 120h, the fifth portion 130h of the insulating sheet 130, and the fourth leg 142d of the metal dome 140. In other words, the fifth pressure sensor C5 is constituted by the electrode 111h, a predetermined part (the fourth leg 142d) of the metal dome 140 supported on the electrode 111h, and an insulator (the fifth portion 130h) between the electrode 111h and the predetermined part. The fifth pressure sensor C5 further includes an elastic member (the fifth elastic member 120h) between the insulator (the fifth portion 130h) and the electrode 111h.

Each of the first, second, fourth, and fifth pressure sensors C1, C2, C4, and C5 is a pressure sensor facing the concave surface 141a of the metal dome 140 and supporting the metal dome 140. As shown in FIG. 19, the first pressure sensor C1 and the second pressure sensor C2 are on opposite sides, in a (first) predetermined direction crossing the central axis of the metal dome 140 (parallel to the left and right directions in FIG. 19), with respect to the center axis of the metal dome 140. In contrast, the first pressure sensor C1 and the second pressure sensor C2 are on the same side, in a second predetermined direction crossing the central axis of the metal dome 140 and the first predetermined direction, with respect to the center axis of the metal dome 140. In the present embodiment, the second predetermined direction is a direction perpendicular to the central axis of the metal dome 140 and the fast predetermined direction and also is a direction in which the first leg 142a and the second leg 142b (or the third leg 142c and the fourth leg 142d) are arranged. In summary, in FIG. 19, the second predetermined direction is parallel to upward and downward directions. Similarly, the fourth pressure sensor C4 and the fifth pressure sensor C5 are on opposite sides, in the first predetermined direction (parallel to the left and right directions in FIG. 19), with respect to the center axis of the metal dome 140. In contrast, the fourth pressure sensor C4 and the fifth pressure sensor C5 are on the same side, in the second predetermined direction (parallel to the upward and downward directions in FIG. 19), with respect to the center axis of the metal dome 140. In particular, the fourth pressure sensor C4 is an additional pressure sensor located on an opposite side from a corresponding pressure sensor which is one of the first pressure sensor C1 and the second pressure sensor C2 (in this situation, the first pressure sensor C1) with regard to the central axis of the metal dome 140 in the second predetermined direction. In addition, the fifth pressure sensor C5 is an additional pressure sensor located on an opposite side from a corresponding pressure sensor which is one of the first pressure sensor C1 and the second pressure sensor C2 (in this situation, the second pressure sensor C2) with regard to the central axis of the metal dome 140 in the second predetermined direction. Therefore, the fourth pressure sensor C4 and the first pressure sensor C1 are on the same side with regard to the central axis of the metal dome 140 in the first predetermined direction. Similarly, the fifth pressure sensor C5 and the second pressure sensor C2 are on the same side with regard to the central axis of the metal dome 140 in the first predetermined direction. Further, each of the first, second, fourth, and fifth pressure sensors C1, C2, C4, and C5 is an electrostatic pressure sensor.

The third pressure sensor C3 is constituted by the electrode 111f of the third electrically conductive member 110f, the third elastic member 120f, the third portion 130f of the insulating sheet 130, and the elastically deformable part 141 of the metal dome 140. The third pressure sensor C3 further includes an elastic member (the third elastic member 120f) between an insulator (the third portion 130f of the insulating sheet 130) and the electrode 111f.

The third pressure sensor C3 is an electrostatic pressure sensor analogous to the first, second, fourth, and fifth pressure sensors C1, C2, C4, and C5. However, the third pressure sensor C3 is different from the first, second, fourth, and fifth pressure sensors C1, C2, C4, and C5 and is not a pressure sensor facing the concave surface 141a of the metal dome 140 and supporting the metal dome 140. The third pressure sensor C3 functions as a similar detector to Embodiment 1.

The input device 100B described above includes the first to fifth pressure sensors C1 to C5. Each of the first to fifth pressure sensors C1 to C5 is an electrostatic pressure sensor and therefore can be used as a proximity sensor for sensing an object with the ground potential (e.g., fingers or hands of an inputter). In one example, the input device 100B can detect fingers or hands of an inputter dose to the metal dome 140 by the first to fifth pressure sensors C1 to C5.

Further, the input device 100B can determine mount of pressing (stroke) of the metal dome 140.

When the central part of the metal dome 140 is pressed, almost equal pressures act on the first, second, fourth, and fifth pressure sensor C1, C2, C4, and C5. Hence, electrostatic capacitances of the first, second, fourth, and fifth pressure sensors C1, C2, C4, and C5 are increased with increase in amount of pressing (stroke) of the metal dome 140. On the other hand, the third pressure sensor C3 does not support the metal dome 140 and therefore sees change in its electrostatic capacitance smaller than those of the first, second, fourth, and fifth pressure sensors C1, C2, C4, and C5. When elastic deformation of the elastically deformable part 141 of the metal dome 140 occurs together with production of a click, the third pressure sensor C3 sees a large change in its electrostatic capacitance.

When a first part of the metal dome 140 in the first predetermined direction (parallel to the left and light directions in FIG. 19) (the left part thereof in FIG. 19, part thereof corresponding to the first and fourth pressure sensors C1 and C4) is pressed, the first pressure sensor C1 sees pressure higher than that acting on the second pressure sensor C2. In addition, the fourth pressure sensor C4 sees pressure higher than that acting on the fifth pressure sensor C5. In contrast, when a second part of the metal dome 140 in the first predetermined direction (parallel to the left and right directions in FIG. 19) (the right part thereof in FIG. 19, part thereof corresponding to the second and fifth pressure sensors C2 and C5) is pressed, the second pressure Sensor C2 sees pressure higher than that acting on the first pressure sensor C1. In addition, the fifth pressure sensor C5 sees pressure higher than that acting on the fourth pressure sensor C4. Such differences in pressure can be measured from changes in electrostatic capacitances of the first, second, fourth, and fifth pressure sensors C1, C2, C4, and C5. Therefore, the input device 100B can identify part of the metal dome 140 pressed by an inputter in the first predetermined direction of the metal dome 140.

When a first part of the metal dome 140 in the second predetermined direction (parallel to the upward and downward directions in FIG. 19) (the lower part thereof in FIG. 19, part thereof corresponding to the first and second pressure sensors C1 and C2) is pressed, the first pressure sensor C1 sees pressure higher than that acting on the fourth pressure sensor C4. In addition, the second pressure sensor C2 sees pressure higher than that acting on the fifth pressure sensor C5. In contrast, when a second part of the metal dome 140 in the second predetermined direction (parallel to the upward and downward directions in FIG. 19) (the upper part thereof in FIG. 19, part thereof corresponding to the fourth and fifth pressure sensors C4 and C5) is pressed, the fourth pressure sensor C4 sees pressure higher than that acting on the first pressure sensor C1. In addition, the fifth pressure sensor C5 sees pressure higher than that acting on the second pressure sensor C2. Such differences in pressure can be measured from changes in electrostatic capacitances of the first, second, fourth, and fifth pressure sensors C1, C2, C4, and C5. Therefore, the input device 100B can identify part of the metal dome 140 pressed by an inputter in the second predetermined direction of the metal dome 140.

Also in the input device 100B, each of the first to fifth pressure sensors C1 to C5 is an electrostatic pressure sensor and therefore can be used as a proximity sensor for sensing an object with the ground potential (e.g., fingers or hands of an inputter). In one example, the input device 100B can detect fingers or hands of an inputter close to the metal dome 140 by the first to fifth pressure sensors C1 to C5.

As shown in FIG. 17, the determination system 200 includes the first to third terminals 200a to 200c. The first to third terminals 200a to 200c are electrically connected to the first to third pressure sensors C1 to C3 of the input device 100B, respectively. For example, the first, second and third terminals 200a, 200b, and 200c are connected to the terminal 112d of the first electrically conductive member 110d, the terminal 112e of the second electrically conductive member 110e, and one terminal 112f of the third electrically conductive member 110f, respectively. By doing so, the determination system 200 is electrically connected to the first, second and third pressure sensors C1, C2, and C3 (the electrodes 111d, 111e, and 111f). In contrast, the determination system 200 is not connected to the fourth and fifth pressure sensors C4 and C5 of the input device 100B directly. As shown in FIG. 17, the fourth and fifth pressure sensors C4 and C5 are grounded.

The determination system 200 is configured to perform the first determination operation and the second determination operation by the obtaining unit 210 and the determining unit 220.

In the first determination operation, the obtaining unit 210 applies a voltage to the first terminal 200a and grounds the second and third terminals 200b and 200c to measure change in electrostatic capacitance of the first pressure sensor C1, as described in relation to Embodiment 1. Further, the fourth and fifth pressure sensors C4 and C5 are grounded. In summary, the obtaining unit 210 obtains change in electrostatic capacitance of the first pressure sensor C1 while the fourth pressure sensor C4 is grounded. Hence, the first pressure sensor C1 is connected to a parallel circuit of the second, third, fourth, and fifth pressure sensors C2, C3, C4, and C5. In this regard, the first and fourth pressure sensors C1 and C4 are on the same side in the first predetermined direction with regard to the central axis of the metal dome 140. Accordingly, when the first end in the first predetermined direction of the metal dome 140 is pressed, not only electrostatic capacitance of the first pressure sensor C1 but also electrostatic capacitance of the fourth pressure sensor C4 may be changed. Therefore, change in electrostatic capacitance of a whole of the input device 100B becomes larger. In conclusion, with regard to pressing of the first end in the first predetermined direction of the metal dome 140, the measurement sensitivity therefor can be improved. This may result in improvement of accuracy for determination of pressed part.

Also in the first determination operation, the obtaining unit 210 applies a voltage to the second terminal 200b and grounds the first and third terminals 200a and 200c to measure change in electrostatic capacitance of the second pressure sensor C2, as described in relation to Embodiment 1. Further, the fourth and fifth pressure sensors C4 and C5 are grounded. In summary, the obtaining unit 210 obtains change in electrostatic capacitance of the second pressure sensor C2 while the fifth pressure sensor C5 is grounded. Hence, the second pressure sensor C2 is connected to a parallel circuit of the first, third, fourth, and fifth pressure sensors C1, C3, C4, and C5. In this regard, the second and fifth pressure sensors C2 and C5 are on the same side in the first predetermined direction with regard to the central axis of the metal dome 140. Accordingly, when the second end in the first predetermined direction of the metal dome 140 is pressed, not only electrostatic capacitance of the second pressure sensor C2 but also electrostatic capacitance of the fifth pressure sensor C5 may be changed. Therefore, change in electrostatic capacitance of a whole of the input device 100B becomes larger. In conclusion, with regard to pressing of the second end in the first predetermined direction of the metal dome 140, the measurement sensitivity therefor can be improved. In the present embodiment, the fourth and fifth pressure sensors C4 and C5 are grounded permanently. Therefore, it is unnecessary to provide the determination system 200 with additional terminals for grounding the fourth and fifth pressure sensors C4 and C5.

### 1.3 Embodiment 3

FIG. 20 shows an input system according to the present embodiment. The input system of the present embodiment includes the input device 100B and a determination system 201.

The determination system 201 is configured to determine input to the input device 100B based on output (an input result) from the input device 100B. In the present embodiment the input result includes values of (changes in) electrostatic capacitances of the first to fifth pressure sensors C1 and C5 of the input device 100B. The determination system 201 may be implemented by one or more processors (microprocessors) and one or more memories, similarly to the determination system 200.

As shown in FIG. 20, the determination system 201 includes first to fifth terminals 200a to 200e. The first to fifth terminals 200a to 200e are electrically connected to the first to fifth pressure sensors C1 to C5 of the input device 100B, respectively. For example, the first, second and third terminals 200a, 200b, and 200c are connected to the terminal 112d of the first electrically conductive member 110d, the terminal 112e of the second electrically conductive member 110e, and one terminal 112f of the third electrically conductive member 110f, respectively. Additionally, the fourth and fifth terminals 200d and 200e are connected to the terminal 112g of the fourth electrically conductive member 110g and the terminal 112h of the fifth electrically conductive member 110h, respectively. By doing so, the determination system 201 is electrically connected to the first to fifth pressure sensors C1 to C5 (the electrodes 111d to 111h).

The determination system 201 is configured to perform the first determination operation and the second determination operation by the obtaining unit 210 and the determining unit 220, similarly to the determination system 200.

In the first determination operation, the obtaining unit 210 sets the sensitivity for determination of changes in electrostatic capacitances, to the first level. Next, the obtaining unit 210 obtains changes in electrostatic capacitances. In detail, the obtaining unit 210 applies a voltage to any one of the first to fourth terminals 200a to 200e and grounds the others. By doing so, the obtaining unit 210 measures changes in electrostatic capacitances of the first to fourth pressure sensors C1 to C4 in turn.

When the obtaining unit 210 obtains changes in electrostatic capacitances of the first to fourth pressure sensors C1 to C4, the determining unit 220 determines which part of the metal dome 140 in the first predetermined direction has been pressed (inclination), based on a balance of changes in electrostatic capacitances of the first and second pressure sensors C1 and C2. In addition, the determining unit 220 determines which part of the metal dome 140 in the second predetermined direction has been pressed (inclination), based on a balance of changes in electrostatic capacitances of the first and fourth pressure sensors C1 and C4.

In detail, based on a result of the comparison between changes in electrostatic capacitances of the first and second pressure sensors C1 and C2, the determining unit 220 determines which part of the metal dome 140 in the first predetermined direction has been pressed (inclination). The determining unit 220 uses a pair of pressure sensors on opposite sides in the first predetermined direction of the metal dome 140 with regard to the central axis of the metal dome 140. In a concrete example, the determining unit 220 compares changes in electrostatic capacitances of the first and second pressure sensors C1 and C2. If change in electrostatic capacitance of the first pressure sensor C1 is larger than change in electrostatic capacitance of the second pressure sensor C2, the determining unit 220 compares that the first end of the metal dome 140 (the left part thereof in FIG. 19, part thereof corresponding to the first and fourth pressure sensors C1 and C4) has been pressed. If change in electrostatic capacitance of the second pressure sensor C2 is larger than change in electrostatic capacitance of the first pressure sensor C1, the determining unit 220 determines that the second end of the metal dome 140 (the right part thereof in FIG. 19, part thereof corresponding to the second and fifth pressure sensors C2 and C5) has been pressed. If change in electrostatic capacitance of the first pressure sensor C1 is equal to change in electrostatic capacitance of the second pressure sensor C1, the determining unit 220 determines that the central part of the metal dome 140 (the center thereof in FIG. 19, part thereof corresponding to the third pressure sensor C3) has been pressed.

In addition, based on a result of the comparison between changes in electrostatic capacitances of the first and fourth pressure sensors C1 and C4, the determining unit 220 determines which part of the metal dome 140 in the second predetermined direction has been pressed (inclination). The determining unit 220 uses a pair of pressure sensors on opposite sides in the second predetermined direction of the metal dome 140 with regard to the central axis of the metal dome 140. In a concrete example, the determining unit 220 compares changes in electrostatic capacitances of the first and fourth pressure sensors C1 and C4. If change in electrostatic capacitance of the first pressure sensor C1 is larger than change in electrostatic capacitance of the fourth pressure sensor C4, the determining unit 220 determines that the third end of the metal dome 140 (the lower part thereof in FIG. 19, part thereof corresponding to the first and second pressure sensors C1 and C2) has been pressed. If change in electrostatic capacitance of the fourth pressure sensor C4 is larger than change in electrostatic capacitance of the first pressure sensor C1, the determining unit 220 determines that the fourth end of the metal dome 140 (the upper part thereof in FIG. 19, part thereof corresponding to the fourth and fifth pressure sensors C4 and C5) has been pressed. If change in electrostatic capacitance of the first pressure sensor C1 is equal to change in electrostatic capacitance of the fourth pressure sensor C4, the determining unit 220 determines that the central part of the metal dome 140 (the center thereof in FIG. 19, part thereof corresponding to the third pressure sensor C3) has been pressed.

Further, the determining unit 220 determines which part of the metal dome 140 has been pressed, based on a combination of pressed parts in the first and second predetermined directions of the metal dome 140. When the pressed part in the first predetermined direction is determined to be the first end and the pressed part in the second predetermined direction is determined to be the third end, the determining unit 220 determines that a first corner of the metal dome 140 (the left and lower part thereof in FIG. 19, part thereof corresponding to the first pressure sensor C1 only) has been pressed. For example, when the pressed part in the first predetermined direction is determined to be the second end and the pressed part in the second predetermined direction is determined to be the third end, the determining unit 220 determines that a second corner of the metal dome 140 (the right and lower part thereof in FIG. 19, part thereof corresponding to the second pressure sensor C2 only) has been pressed. For example, when the pressed part in the first predetermined direction is determined to be the first end and the pressed part in the second predetermined direction is determined to be the fourth end, the determining unit 220 determines that a third corner of the metal dome 140 (the left and upper part thereof in FIG. 19, part thereof corresponding to the fourth pressure sensor C4 only) has been pressed. For example, when the pressed part in the first predetermined direction is determined to be the second end and the pressed part in the second predetermined direction is determined to be the fourth end, the determining unit 220 determines that a fourth corner of the metal dome 140 (the right and upper part thereof in FIG. 19, part thereof corresponding to the fifth pressure sensor C5 only) has been pressed. For example, it is supposed that the pressed part in the first predetermined direction is determined to be the first end and the pressed part in the second predetermined direction is determined to be the central part. In this supposition, the determining unit 220 determines that a center of the first end of the metal dome 140 (the center part of the left side thereof in FIG. 19, part thereof between the first and fourth pressure sensors C1 and C4) has been pressed. For example, it is supposed that the pressed part in the first predetermined direction is determined to be the second end and the pressed part in the second predetermined direction is determined to be the central part. In this supposition, the determining unit 220 determines that a center of the second end of the metal dome 140 (the center part of the right side thereof in FIG. 19, part thereof between the second and fifth pressure sensors C2 and C5) has been pressed. For example, it is supposed that the pressed part in the first predetermined direction is determined to be the center part and the pressed part in the second predetermined direction is determined to be the third end. In this supposition, the determining unit 220 determines that a center of the third end of the metal dome 140 (the center part of the lower side thereof in FIG. 19, part thereof between the first and second pressure sensors C1 and C2) has been pressed. For example, it is supposed that the pressed part in the first predetermined direction is determined to be the center part and the pressed part in the second predetermined direction is determined to be the fourth end. In this supposition, the determining unit 220 determines that a center of the fourth end of the metal dome 140 (the center part of the upper side thereof in FIG. 19, part thereof between the fourth and fifth pressure sensors C4 and C5) has been pressed. For example, if the pressed parts in the first and second predetermined directions both are determined to be the center parts, the determining unit 220 determines that the center of the metal dome 140 (the center part thereof in FIG. 19, part thereof corresponding to the third pressure sensor C3 only) has been pressed.

Additionally, the determining unit 220 determines whether change in electrostatic capacitance of the third pressure sensor C3 exceeds the prescribed value. If change in electrostatic capacitance of the third pressure sensor C3 exceeds the prescribed value, the determining unit 220 determines that a click has been produced.

In the second determination operation, the obtaining unit 210 sets the sensitivity for measuring changes in electrostatic capacitances to the second level. The second level is selected to be higher than the first level. Next, the obtaining unit 210 obtains changes in electrostatic capacitances. When the obtaining unit 210 obtains changes in electrostatic capacitances of the first to fifth pressure sensors C1 to C5, the determining unit 220 determines whether changes in electrostatic capacitances of the first to fifth pressure sensors C1 to C5 exceed respective prescribed values. If change in electrostatic capacitance of the first pressure sensor C1 exceeds the corresponding prescribed value, the determining unit 220 determines that fingers of an inputter is in a vicinity of the first corner of the metal dome 140 (the left and lower part thereof in FIG. 19, part thereof corresponding to the first pressure sensor C1 only). If change in electrostatic capacitance of the second pressure sensor C2 exceeds the corresponding prescribed value, the determining unit 220 determines that fingers of an inputter is in a vicinity of the second corner of the metal dome 140 (the right and lower part thereof in FIG. 19, part thereof corresponding to the second pressure sensor C2 only). If change in electrostatic capacitance of the third pressure sensor C3 exceeds the corresponding prescribed value, the determining unit 220 determines that fingers of an inputter is in a vicinity of the center of the metal dome 140 (the center part thereof in FIG. 19, part thereof corresponding to the third pressure sensor C3 only). If change in electrostatic capacitance of the fourth pressure sensor C4 exceeds the corresponding prescribed value, the determining unit 220 determines fingers of an inputter is in a vicinity of the third corner of the metal dome 140 (the left and upper part thereof in FIG. 19, part thereof corresponding to the fourth pressure sensor C4 only). If change in electrostatic capacitance of the fifth pressure sensor C5 exceeds the corresponding prescribed value, the determining unit 220 determines fingers of an inputter is in a vicinity of the fourth corner of the metal dome 140 (the right and upper part thereof in FIG. 19, part thereof corresponding to the fifth pressure sensor C5 only). Note that, the prescribed values for the first to fifth pressure sensors C1 to C5 may be different or same.

### 1.4 Embodiment 4

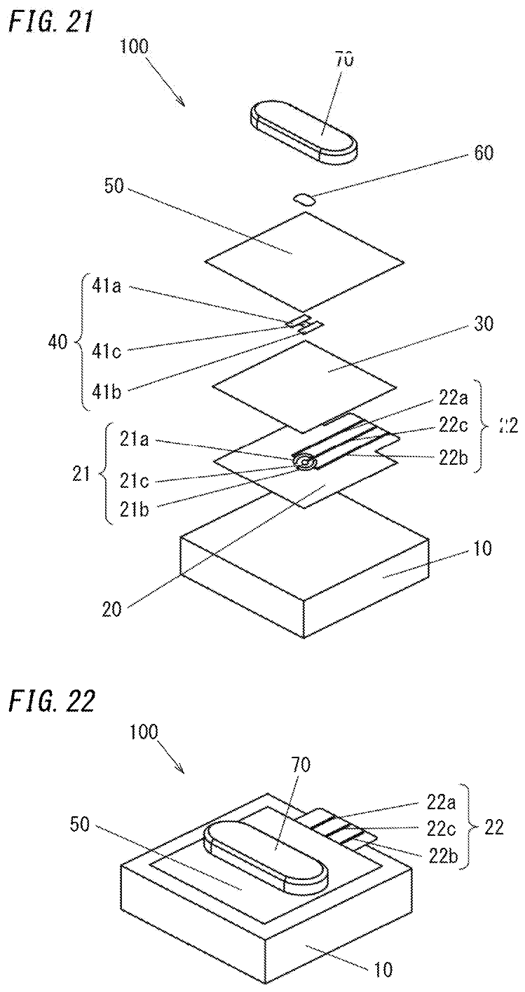

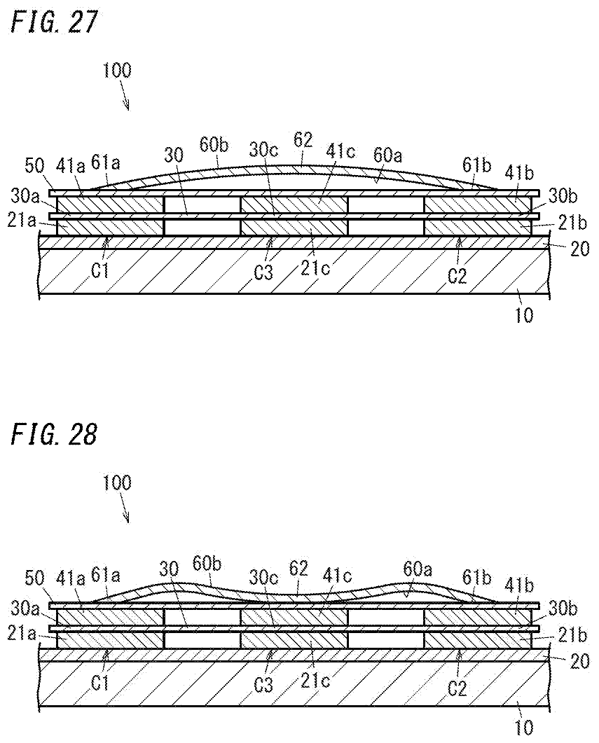

FIG. 21 shows an input device 100 used in an input system of the present embodiment. As shown in FIG. 27 and FIG. 28, the input device 100 includes a substrate 10, pressure sensors placed on the substrate 10 (the first pressure sensor C1, the second pressure sensor C2, and the third pressure sensor), and a metal dome 60 placed on the pressure sensors C1, C2, and C3. According to the input device 100 of the present embodiment, pressing force directed to the pressure sensors C1, C2, and C3 is transferred to the pressure sensors C1, C2, and C3 by way of the metal dome 60. The metal dome 60 is elastically deformed by such pressing force and then can produce a click. Therefore, it is possible to provide the input device 100 which includes the pressure sensors C1, C2, and C3 yet can produce a click.

Further, in the input device 100, the three pressure sensors C1, C2, and C3 include specific pressure sensors C1 and C2 which face a concave surface 60a of the metal dome 60 and support the metal dome 60. Therefore, even before the metal dome 60 is elastically deformed and then a click is produced, pressing force applied on the metal dome 60 (pressing force applied on a convex surface 60b of the metal dome 60) can be measured by the pressure sensors C1 and C2. After the metal dome 60 is elastically deformed and then a click is produced, pressing force applied on the metal dome 60 can be measured by the pressure sensors C1, C2, and C3. To sum up, irrespective of production of a click (irrespective of occurrence of elastic deformation of the metal dome 60), pressing force on the metal dome 60 can be measured.

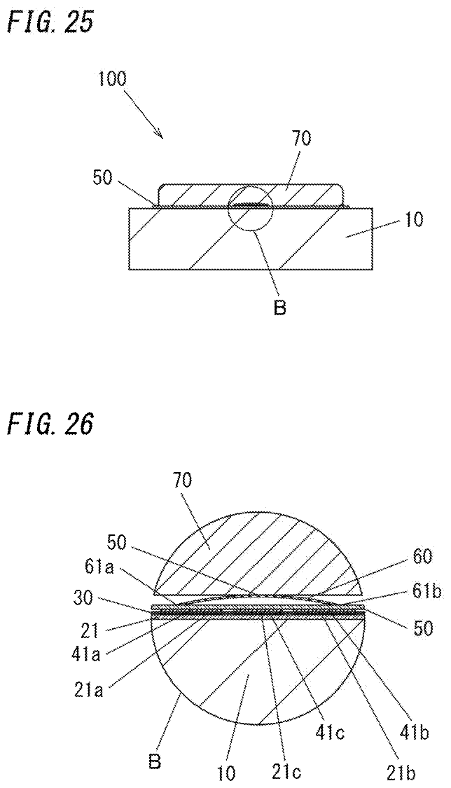

Hereinafter, using FIG. 21 to FIG. 28, the input device 100 is described. As shown in FIG. 21, the input device 100 includes the substrate 10, a printed substrate 20, an insulating sheet 30, an electrically conductive sheet 40, a protective sheet 50, the metal dome 60, and a pressing member 70. Further, the input device 100 includes a cover which is attached to the substrate 10 and constitutes a housing together with the substrate 10. The cover exposes the pressing member 70 to be allowed to be operated. As shown in FIG. 22, the printed substrate 20 is placed on the substrate 10. In particular, the substrate 10 has a rectangular flat plate shape. The printed substrate 20 is placed on a surface in a thickness axis of the substrate 10 (an upper surface thereof in FIG. 21).

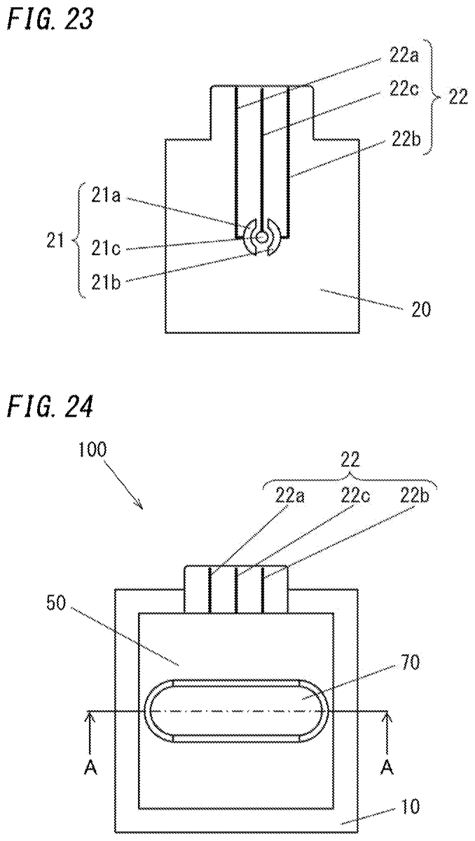

As shown in FIG. 23, the printed substrate 20 includes an electrode 21 and a conductive line 22 electrically connected to the electrode 21. For example, the electrode 21 and the conductive line 22 are patterned conductors formed on an insulating substrate.

As shown in FIG. 23, the electrode 21 include a first electrode 21a, a second electrode 21b, and a third electrode 21c. The first electrode 21a and the second electrode 21b are formed into arc shapes. The first electrode 21a and the second electrode 21b are arranged opposite each other. The third electrode 21c is formed into a circle shape. The third electrode 21c is placed between the first electrode 21a and the second electrode 21b. Note that, as shown in FIG. 23, the first electrode 21a, the second electrode 21b, and the third electrode 21c are formed as separate parts.

As shown in FIG. 23, the conductive line 22 include a first conductive line 22a electrically connected to the first electrode 21a, a second conductive line 22b electrically connected to the second electrode 21b, and a third conductive line 22c electrically connected to the third electrode 21c. The first conductive line 22a, the second conductive line 22b, and the third conductive line 22c each are connected to a micro control unit. Note that, as shown in FIG. 23, the first conductive line 22a, the second conductive line 22b, and the third conductive line 22c are formed as separate parts.

The insulating sheet 30 is placed on the printed substrate 20. And, the insulating sheet 30 covers the printed substrate 20. In particular, the insulating sheet 30 has electrically insulating properties. The insulating sheet 30 covers at least the first electrode 21a, the second electrode 21b, and the third electrode 21c of the printed substrate 20. Further, the insulating sheet 30 does not cover opposite end of the conductive line 22 from the electrode 21.

The electrically conductive sheet 40 is placed on the insulating sheet 30. Further, the electrically conductive sheet 40 is placed facing the electrode 21 with the insulating sheet 30 in-between. The electrically conductive sheet 40 includes a first electrically conductive part 41a, a second electrically conductive part 41b, and a third electrically conductive part 41c. Note that, as shown in FIG. 21, the first electrically conductive part 41a, the second electrically conductive part 41b, and the third electrically conductive part 41c are formed as separate parts.

The first electrically conductive part 41a is placed in a position corresponding to the first electrode 21a. The second electrically conductive part 41b is placed in a position corresponding to the second electrode 21b. The third electrically conductive part 41c is placed in a position corresponding to the third electrode 21c.

Stated differently, the first electrically conductive part 41a and the second electrically conductive part 41b are placed facing each other. The third electrically conductive part 41c is placed between the first electrically conductive part 41a and the second electrically conductive part 41b.

The protective sheet 50 is placed on the electrically conductive sheet 40. The protective sheet 50 covers the electrically conductive sheet 40. Especially, the protective sheet 50 covers the first electrically conductive part 41a, the second electrically conductive part 41b, and the third electrically conductive part 41c collectively.

The metal dome 60 is a metal plate curving in its thickness axis. As shown in FIG. 27, a first surface in the thickness axis of the metal dome 60 (the lower surface in FIG. 27) defines the concave surface 60a and a second surface (the upper surface in FIG. 27) defines the convex surface 60b. When the convex surface 60b of the metal dome 60 is pressed, the metal dome 50 is elastically deformed as shown in FIG. 28 and thus a click is produced.

As shown in FIG. 27, the metal dome 60 is placed on the protective sheet 50 so as to be convex upward. Further, the metal dome 60 is placed in a position corresponding to the electrically conductive sheet 40.

The metal dome 60 includes a first edge 61a, a second edge 61b, and a top 62. The first edge 61a is placed in a position corresponding to the first electrically conductive part 41a and is in contact with the protective sheet 50. The second edge 61b is placed in a position corresponding to the second electrically conductive part 41b and is in contact with the protective sheet 50. The top 62 is formed between the first edge 61a and the second edge 61b so as to be convex upward. The top 62 is placed in a position corresponding to the third electrically conductive part 41c. For example, the first edge 61a and the second edge 61b are opposite ends in the length axis of the metal dome 60 and the top 62 is a central part in the length axis of the metal dome 60.

The pressing member 70 is placed on the metal dome 60. And, the pressing member 70 is in contact with the top 62. In particular, the pressing member 70 has electrically insulating properties. The pressing member 70 has a rectangular plate shape with a length. The pressing member 70 has an outer shape larger than an outer shape of the metal dome 60. The pressing member 70 has a surface in its thickness axis, which is in contact with the convex surface 60b of the metal dome 60.

The input device 100 is formed as described above. The electrode 21, the electrically conductive sheet 40, and the insulating sheet 30 placed between the electrode 21 and the electrically conductive sheet 40 function as capacitors with electrostatic capacitances. In other words, the printed substrate 20, the insulating sheet 30, and the electrically conductive sheet 40 constitute electrostatic pressure sensors (the first pressure sensor C1, the second pressure sensor C2, and the third pressure sensor C1). In more detail, as shown in FIG. 27 and FIG. 28, the first pressure sensor C1 is constituted by the first electrode 21a, the first electrically conductive part 41a, and a first portion 30a of the insulating sheet 30. The first portion 30a of the insulating sheet 30 is portion of the insulating sheet 30 and sandwiched between the first electrode 21a and the first electrically conductive part 41a. And, the second pressure sensor C2 is constituted by the second electrode 21b, the second electrically conductive part 41b, and a second portion 30b of the insulating sheet 30. The second portion 30b of the insulating sheet 30 is portion of the insulating sheet 30 and sandwiched between the second electrode 21b and the second electrically conductive part 41b. And, the third pressure sensor C3 is constituted by the third electrode 21c, the third electrically conductive part 41c, and a third portion 30c of the insulating sheet 30. The third portion 30c of the insulating sheet 30 is portion of the insulating sheet 30 and sandwiched between the third electrode 21c and the third electrically conductive part 41c.

When inputter (user) presses the pressing member 70 as if lightly touching it, the pressing member 70 slightly presses the metal dome 60. This pressing force presses the first electrically conductive part 41a and the second electrically conductive part 41b by way of the first edge 61a and the second edge 61b. This may cause change in electrostatic capacitance given by the electrode 21, the electrically conductive sheet 40, and the insulating sheet 30 placed between the electrode 21 and the electrically conductive sheet 40. Especially, electrostatic capacitances of the first pressure sensor C1 and the second pressure sensor C2 may be changed. Such changes in electrostatic capacitances are measured by the micro control unit connected to the input device 100 via the conductive line 22.

In that case, the pressing force does not cause a click, but the pressing force can be measured. In other words, the input device 100 can detect a touch (a touch of the pressing member 70 by an inputter). Stated differently, even before the metal dome 60 is elastically deformed and then a click is produced, pressing force applied on the metal dome 60 (pressing force applied on the convex surface 60b of the metal dome 60) can be measured by the pressure sensors C1 and C2.

An inputter further presses the pressing member 70, the metal dome 60 is elastically deformed together with production of a click. The click produced by the metal dome 60 is transferred to the inputter through the pressing member 70. Thus, the inputter can feel the click.

Such elastic deformation of the metal dome 60 allows the top 62 to press the third electrode 21c as shown in FIG. 28. In this situation, the first electrically conductive part 41a, the second electrically conductive part 41b, and the third electrically conductive part 41c can be pressed by way of the first edge 61a, the second edge 61b, and the top 62. Accordingly, change in electrostatic capacitance of the third pressure sensor C3 is caused in addition to changes in electrostatic capacitances of the first pressure sensor C1 and the second pressure sensor C2. Therefore, after the metal dome 60 is elastically deformed and then a click is produced, pressing force applied on the metal dome 60 can be measured by the pressure sensors C1, C2, and C3. Use of the metal dome 60 can increase changes in electrostatic capacitances.

When pressing force just causing elastic deformation of the metal dome 60 is used as a threshold value, the third electrically conductive part 41c and the third electrode 21c (i.e., the third pressure sensor C3) can be used as a sensor for determining whether pressing force equal to or larger than the threshold value is applied to the input device 100. The pressing force just causing elastic deformation of the metal dome 60 is equal to pressing force on the metal dome 60 required to cause elastic deformation of the metal dome 60. Accordingly, change in electrostatic capacitance of the third pressure sensor C3 enables determination as to whether a click is produced.

These changes in electrostatic capacitances (changes in individual electrostatic capacitances of the pressure sensors C1, C2, and C3) can be measured by the micro control unit. The micro control unit outputs an input signal based on results of measurements. In this regard, the micro control unit can be replaced with the determination system 200 of Embodiment 1. In other words, the input device 100 and the determination system 200 may constitute an input system.

### 2. Variations

The aforementioned embodiments are some of various embodiments according to the present disclosure. The above embodiments may be modified in accordance with design or the like, provided they still can achieve the purpose of the present disclosure. The following is a list of possible variations of the above embodiments.

As shown in FIG. 9, changes in electrostatic capacitances caused by elastic deformation of the metal dome 140 can be seen in the first and second pressure sensors C1 and C2. Therefore, production of a click can be detected by use of the first and second pressure sensors C1 and C2. In this case, the input device (100; 100A; 100B) may not necessarily include the third pressure sensor C3.

In the input device (100; 100A; 100B), the number of pressure sensors may not be limited particularly as long as it is two or more. For example, in the input device 100B, the two pressure sensors C1 and C2 (or C4 and C5) are arranged in the first predetermined direction but three or more pressure sensors may be arranged in line. In the input device 100B, the two pressure sensors C1 and C4 (or C2 and C5) are arranged in the second predetermined direction but three or more pressure sensors may be arranged in line. In the input device (100; 100A; 100B), a plurality of pressure sensors may be arranged in a matrix (e.g., 2 by 2, 2 by 3, and 3 by 3).

In the input device 100A, the first to third elastic members 120a to 120c may not be electrically conductive. As to each of the first to third elastic members 120a to 120c, opposite surfaces in the thickness axis thereof may be rough surfaces or flat surfaces. Further, the first to third elastic members 120a to 120c may be omitted. This can also apply to the input device 100B.

Further, shapes of components of the input device (100; 100A; 100B) may not be limited to shapes of those of the above embodiments. For example, the outer shape of the metal dome 140 may not be limited to the aforementioned outer shape and the shape of the elastically deformable part 141 may not be limited particularly. The metal dome 140 may be constituted by the elastically deformable part 141 only. However, the metal dome 140 can be placed more stably when it includes the legs 142a to 142b. The shape of the pressing member 150 may be a shape other than the disk shape (e.g., a rectangular plate shape). The shape of the housing 160 may be a shape other than the flat quadrangle box shape (e.g., a hollow cylindrical shape).

Further, in the input device (100; 100A; 100B), shapes of electrodes (21a to 21c; 111a to 111c; 111d to 111h) may not be limited to shapes of those in the embodiments and may be modified suitably in accordance with the shape of the metal dome (60; 140) and/or applications of pressure sensors.

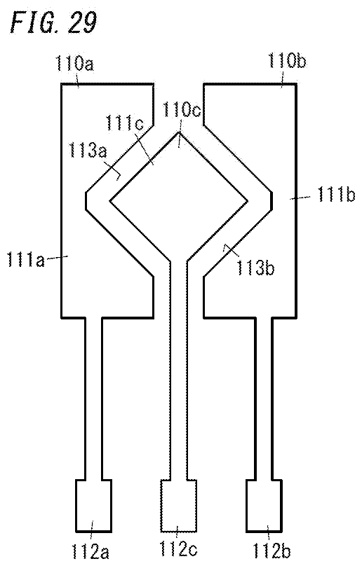

For example, FIG. 29 shows variations of the electrodes 111a to 111c of the first, second, and third electrically conductive members 110a to 110c of the input device 100A of Embodiment 1. In FIG. 29, the electrode 111c has a square plate shape. The electrodes 111a and 111b have rectangular plate shapes but include triangle cutouts 113a and 113b in sides close to the electrode 111c for avoiding interference with the electrode 111c.

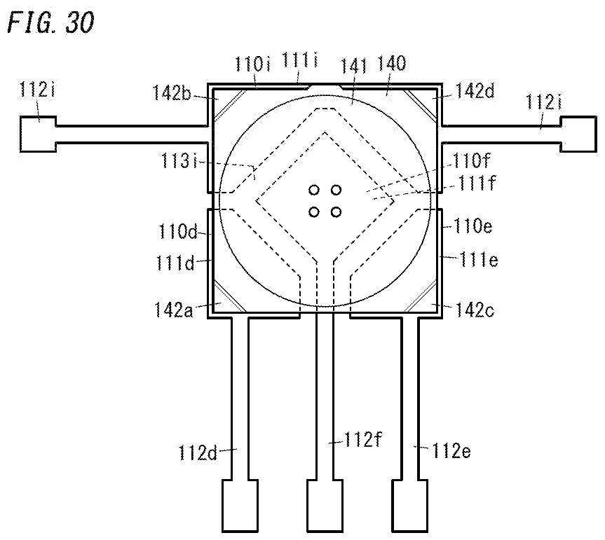

For example, in the input system of Embodiment 2, the fourth and fifth pressure sensors C4 and C5 of the input device 100B are grounded. Therefore, the electrodes 111g and 111h of the fourth and fifth electrically conductive member 110g and 110h may be electrically connected to each other. FIG. 30 shows a variation of the input device 100B of the input system of Embodiment 2. In the variation shown in FIG. 30, the electrode 111f has a square plate shape. Further, in this variation, a sixth electrically conductive member 110i is used instead of the fourth and fifth electrically conductive members 110g and 110h. The sixth electrically conductive member 110i includes an electrode 111i and a pair of terminals 112i. The electrode 111i has a rectangular plate shape but includes a triangle cutout 113i in a side close to the electrode 111f for avoiding interference with the electrode 111f. The pair of terminals 112i protrudes from opposite ends in a length axis of the electrode 111i. Note that, the electrodes 111d and 111e have tapered corners close to the electrode 111f for avoiding interference with the electrode 111f.

In the input device 100A, the pair of terminals 112a, the pair of terminals 112b, and the pair of terminals 112c may protrude from not the second surface in the thickness axis of the body 161 of the housing 160 but a side surface thereof. According to this, undesired effects of flux used in mounting the input device 100A can be reduced. This configuration may apply to the input device 100B. Also the terminals 112d, 112e, 112f, 112g, and 112h may protrude from not the second surface in the thickness axis of the body 161 of the housing 160 but the side surface.

In the input device 100, when direct contact between the electrically conductive sheet 40 and the electrode 21 is prevented, the insulating sheet 30 may not be necessarily required to cover the printed substrate 20 as shown in FIG. 21. Similarly, the protective sheet 50 may have a shape and size capable of preventing direct contact between the metal dome 60 and the electrically conductive sheet 40.

Similarly in the input device 100A, the insulating sheet 130 may not be necessarily required to cover the first to third elastic members 120a, 120b, and 120c collectively. It is sufficient that the insulating sheet 130 can prevent direct contact between the metal dome 140 and the first to third electrically conductive members 110a to 110c. Thus, in the input device 100A, the insulating sheet 130 may include at least the first to third portions 130a to 130c. This configuration may apply to the input device 100B and the insulating sheet 130 may include at least the first to fifth portions 130d to 130h. In this regard, surfaces of the metal dome 140 corresponding to the first to third elastic members 120a, 120b, and 120c may be covered with insulating layers or subjected to insulating treatment. In this case, the insulating sheet 130 can be omitted. This configuration also may apply to the input device 100B.

In the determination system 201, the determining unit 220 may use the fifth pressure sensor C5 for determining which part has been pressed. For example, the determining unit 220 may determine which part of the metal dome 140 in the first predetermined direction has been pressed (inclination), based on a balance between changes in electrostatic capacitances of the fourth and fifth pressure sensors C4 and C5. Or, the determining unit 220 may determine which part of the metal dome 140 in the second predetermined direction has been pressed (inclination), based on a balance between changes in electrostatic capacitances of the second and fifth pressure sensors C2 and C5. The determining unit 220 may determine which part of the metal dome 140 has been pressed, by use of results of these determinations, and consequently accuracy of determination can be improved.

In the determination system (200; 201), the obtaining unit 210 obtains changes in electrostatic capacitances from a plurality of pressure sensors, individually but may treat two or more of the plurality of pressure sensors as a single pressure sensor and obtain change in electrostatic capacitance from that single pressure sensor.

For example, the determination system 200 determines whether a detection target (e.g., fingers of an inputter) is in a vicinity of the metal dome 140, based on each of the plurality of pressure sensors C1 to C3. In this regard, the determination system 200 may use two or more pressure sensors as a single sensor and determine based on this single sensor whether a detection target (e.g., fingers of an inputter) is in a vicinity of the metal dome 140. For example, in step S21, the determination system 200 may apply voltages to all of the first to third terminals 200a to 200c. By doing so, the first to third pressure sensors C1 to C3 functions as a single pressure sensor. Hence, the determination system 200 can obtain the sum of changes in electrostatic capacitances of the first to third pressure sensors C1 to C3 and determine whether a detection target is approaching, based on this sum. In other words, it is possible to improve accuracy of determination as to whether a detection target is approaching, instead of determining which pressure sensor of the plurality of pressure sensors the detection target is approaching. This configuration may apply to the determining unit 220 of the determination system 201. Note that, there is no need to use all of a plurality of pressure sensors as a single sensor, but using two or more of the plurality of pressure sensors as a single sensor can contribute to improvement of sensitivity.

For example, to determine: which part in the first predetermined direction has been pressed; and amount of pressing, the determination system 201 may use the first and fourth pressure sensors C1 and C4 as a single pressure sensor and also use the second and fifth pressure sensors C2 and C5 as another single pressure sensor. In summary, based on a result of comparison between the sum of changes in electrostatic capacitances of the first and fourth pressure sensors C1 and C4 and the sum of changes in electrostatic capacitances of the second and fifth pressure sensors C2 and C5, the determining unit 220 may determine which part in the first predetermined direction of the metal dome 140 has been pressed, and amount of pressing. In this case, the obtaining unit 210 applies voltages to the terminals 112d and 112g and pumas the terminals 112e, 112f, and 112h, thereby obtaining the sum of changes in electrostatic capacitances of the first and fourth pressure sensors C1 and C4. Similarly, the obtaining unit 210 applies voltages to the terminals 112e and 112h and grounds the terminals 112d, 112f, and 112g, thereby obtaining the sum of changes in electrostatic capacitances of the second and fifth pressure sensors C2 and C5. According to this, it is possible to improve detection accuracies for which part in the first predetermined direction has been pressed, and amount of such pressing. Likewise, to determine: which part in the second predetermined direction has been pressed; and amount of pressing, the determination system 201 may use the first and second pressure sensors C1 and C2 as a single pressure sensor and also use the fourth and fifth pressure sensors C4 and C5 as another single pressure sensor. In summary, based on a result of comparison between the sum of changes in electrostatic capacitances of the first and second pressure sensors C1 and C2 and the sum of changes in electrostatic capacitances of the fourth and fifth pressure sensors C4 and C5, the determining unit 220 may determine which part in the second predetermined direction of the metal dome 140 has been pressed, and amount of pressing. In this case, the obtaining unit 210 applies voltages to the terminals 112d and 112e and grounds the terminals 112f, 112g, and 112h, thereby obtaining the sum of changes in electrostatic capacitances of the first and second pressure sensors C1 and C2. Similarly, the obtaining unit 210 applies voltages to the terminals 112g and 112h and wands the terminals 112d, 112e, and 112f, thereby obtaining the sum of changes in electrostatic capacitances of the fourth and fifth pressure sensors C4 and C5. According to this, it is possible to improve detection accuracies for which part in the second predetermined direction has been pressed, and amount of such pressing.

### 3. Aspects

As apparent form the above embodiments and variations, a first aspect is a determination system (200; 201) which is a system for determining, based on output from an input device (100; 100A; 100B), input to the input device (100; 100A; 100B). The input device (100; 100A; 100B) includes a metal dome (60; 140) and a plurality of pressure sensors (C1, C2, C3, C4, C5) which are electrostatic pressure sensors and placed facing a concave surface (60a, 141a) of the metal dome (60; 140). The plurality of pressure sensors (C1, C2, C3, C4, C5) include a fast and second pressure sensors (C1, C2) winch are on opposite sides, in a predetermined direction crossing a central axis of the metal dome (60; 140), with respect to the center axis and which support the metal dome (60; 140). The determination system (200; 201) includes; an obtaining unit (210) configured to obtain changes in electrostatic capacitances of the first and second pressure sensors (C1, C2) from the input device (100; 100A; 100B); and a determining unit (220) configured to determine which part of the metal dome (60, 140) in the predetermined direction has been pressed, based on a balance between changes in electrostatic capacitances of the first and second pressure sensors (C1, C2). According to the first aspect, it is possible to determine which part has been pressed in a pressure sensor equipped input device capable of producing a click when pressed.

A second aspect is a determination system (200; 201) which would be realized in combination with the first aspect. In the second aspect, the plurality of pressure sensors (C1, C2, C3, C4, C5) include a third pressure sensor (C3) placed facing the concave surface of the metal dome (60; 140) but spaced apart from the metal dome (60; 140). The obtaining unit (210) is configured to obtain change in electrostatic capacitance of the third pressure sensor (C3) from the input device (100; 100A; 100B). The determining unit (220) is configured to determine whether the metal dome (60; 140) has been elastically deformed, based on change in electrostatic capacitance of the third pressure sensor (C3). According to the second aspect, it is possible to determine whether a click has been produced.

A third aspect is a determination system (200; 201) which would be realized in combination with the first car second aspect. In the third aspect, the predetermined direction defines a first predetermined direction. The plurality of pressure sensors (C1, C2, C3, C4, C5) include an additional pressure sensor (C4; C5) supporting the metal dome (60; 140).

The additional pressure sensor (C4; C5) is located on an opposite side from a corresponding pressure sensor (C1; C2) which is one of the first pressure sensor (C1) and the second pressure sensor (C2) with regard to the central axis of the metal dome (60; 140) in a second predetermined direction crossing the central axis of the metal dome (60; 140) and the first predetermined direction. The obtaining unit (210) is configured to obtain change in electrostatic capacitance of the additional pressure sensor (C4; C5) from the input device (100; 100A; 100B). The determining unit (220) is configured to determine which part of the metal dome (60; 140) in the second predetermined direction has been pressed, based on a balance between changes in electrostatic capacitances of the corresponding pressure sensor (C1; C2) and the additional pressure sensor (C4; C5). According to the third aspect, it is possible to determine which part has been pressed in a plane defined by the first predetermined direction and the second predetermined direction.

A fourth aspect is a determination system (200; 201) which would be realized in combination with the first or second aspect. In the fourth aspect, the plurality of pressure sensors (C1, C2, C3, C4, C5) include fourth and fifth pressure sensors (C4, C5) supporting the metal dome (60; 140). The fourth pressure sensor (C4) and the first pressure sensor (C1) are on a same side with regard to the central axis of the metal dome (60; 140) in the predetermined direction. The fifth pressure sensor (C5) and the second pressure sensor (C2) are on a same side with regard to the central axis of the metal dome (60; 140) in the predetermined direction. The obtaining unit (210) is configured to obtain change in electrostatic capacitance of the first pressure sensor (C1) while the fourth pressure sensor (C4) is grounded and to obtain change in electrostatic capacitance of the second pressure sensor (C2) while the fifth pressure sensor (C5) is grounded. According to the fourth aspect, it is possible to improve accuracy for determining which part has been pressed.

A fifth aspect is a determination system (200; 201) which would be realized in combination with any one of the first to fourth aspects. In the fifth aspect, the determining unit (220) is configured to determine whether a detection target is present near the metal dome (60; 140), based on changes in electrostatic capacitances of the plurality of pressure sensors (C1, C2, C3, C4, C5). According to the fifth aspect, it is possible to determine whether a detection target is present near the metal dome (60; 140).

A sixth aspect is a determination system (200; 201) which would be realized in combination with the fifth aspect. In the sixth aspect, the obtaining unit (210) is configured to switch sensitivity for obtaining changes in electrostatic capacitances of the plurality of pressure sensors (C1, C2, C3, C4, C5) from the input device (100; 100A; 100B), between a first level and a second level higher than the first level. The determining unit (220) is configured to determine whether a detection target is present near the metal dome (60; 140), based on changes in electrostatic capacitances of the plurality of pressure sensors (C1, C2, C3, C4, C5) while the sensitivity is set to the second level. According to the sixth aspect, it is possible to improve accuracy for determining whether a detection target is present near the metal dome (60; 140).

A seventh aspect is a determination method which is a method for determining, based on output from an input device (100; 100A; 100B), input to the input device (100; 100A; 100B). The input device (100; 100A; 100B) includes a metal dome (60; 140) and a plurality of pressure sensors (C1, C2, C3, C4, C5) which are electrostatic pressure sensors and placed facing a concave surface (60a, 141a) of the metal dome (60; 140). The plurality of pressure sensors (C1, C2, C4, C5) include first and second pressure sensors (C1, C2) which are on opposite sides, in a predetermined direction crossing a central axis of the metal dome (60; 140), with respect to the center axis and which support the metal dome (60; 140). The determination method includes; obtaining changes in electrostatic capacitances of the first and second pressure sensors (C1, C2) from the input device (100; 100A; 100B); and determining which part of the metal dome (60; 140) in the predetermined direction has been pressed, based on a balance between changes in electrostatic capacitances of the first and second pressure sensors (C1, C2). According to the seventh aspect, it is possible to determine which part has been pressed in a pressure sensor equipped input device capable of producing a click when pressed.

An eighth aspect is a determination program which is a program for enabling one or more processors to execute the determination method according to the seventh aspect. According to the eighth aspect, it is possible to determine which part has been pressed in a pressure sensor equipped input device capable of producing a click when pressed.

### REFERENCE SIGNS LIST

100, 100A, 100B Input Device
C1, C2, C3, C4, C5 Pressure Sensor
60 Metal Dome
60a Concave Surface
140 Metal Dome
141a Concave Surface
200, 201 Determination System
210 Obtaining Unit
220 Determining Unit

1. A determination system for determining, based on output from an input device, input to the input device,
the input device including a metal dome and a plurality of pressure sensors which are electrostatic pressure sensors and placed facing a concave surface of the metal dome,
the plurality of pressure sensors including first and second pressure sensors which are on opposite sides, in a predetermined direction crossing a central axis of the metal dome, with respect to the center axis and which support the metal dome, and
the determination system comprising;
an obtaining unit configured to obtain changes in electrostatic capacitances of the first and second pressure sensors from the input device; and
a determining unit configured to determine which part of the metal dome in the predetermined direction has been pressed, based on a balance between changes in electrostatic capacitances of the first and second pressure sensors.

2. The determination system according to claim 1, wherein:
the plurality of pressure sensors include a third pressure sensor placed facing the concave surface of the metal dome but spaced apart from the metal dome;
the obtaining unit is configured to obtain change in electrostatic capacitance of the third pressure sensor from the input device; and
the determining unit is configured to determine whether the metal dome has been elastically deformed, based on change in electrostatic capacitance of the third pressure sensor.

3. The determination system according to claim 1, wherein:
the predetermined direction defines a first predetermined direction;
the plurality of pressure sensors include an additional pressure sensor supporting the metal dome;
the additional pressure sensor is located on an opposite side from a corresponding pressure sensor which is one of the first pressure sensor and the second pressure sensor with regard to the central axis of the metal dome in a second predetermined direction crossing the central axis of the metal dome and the first predetermined direction; and
the obtaining unit is configured to obtain change in electrostatic capacitance of the additional pressure sensor from the input device; and
the determining unit is configured to determine which part of the metal dome in the second predetermined direction has been pressed, based on a balance between changes in electrostatic capacitances of the corresponding pressure sensor and the additional pressure sensor.

4. The determination system according to claim 1, wherein:
the plurality of pressure sensors include fourth and fifth pressure sensors supporting the metal dome;
the fourth pressure sensor and the first pressure sensor are on a same side with regard to the central axis of the metal dome in the predetermined direction;
the fifth pressure sensor and the second pressure sensor are on a same side with regard to the central axis of the metal dome in the predetermined direction; and
the obtaining unit is configured to obtain change in electrostatic capacitance of the first pressure sensor while the fourth pressure sensor is grounded and to obtain change in electrostatic capacitance of the second pressure sensor while the fifth pressure sensor is grounded.

5. The determination system according to claim 1, wherein
the determining unit is configured to determine whether a detection target is present near the metal dome, based on changes in electrostatic capacitances afire plurality of pressure sensors.

6. The determination system according to claim 5, wherein:
the obtaining unit is configured to switch sensitivity for obtaining changes in electrostatic capacitances of the plurality of pressure sensors from the input device, between a first level and a second level higher than the first level; and
the determining unit is configured to determine whether a detection target is present near the metal dome, based on changes in electrostatic capacitances of the plurality of pressure sensors while the sensitivity is set to the second level.

7. A determination method for determining, based on output from an input device, input to the input device,
the input device including a metal dome and a plurality of pressure sensors which are electrostatic pressure sensors and placed facing a concave surface of the metal dome,
the plurality of pressure sensors including first and second pressure sensors which are on opposite sides, in a predetermined direction crossing a central axis of the metal dome, with respect to the center axis and which support the metal dome, and
the determination method comprising;
obtaining changes in electrostatic capacitances of the first and second pressure sensors from the input device; and
determining which part of the metal dome in the predetermined direction has been pressed, based on a balance between changes in electrostatic capacitances of the first and second pressure sensors.

8. A non-transitory computer-readable medium recording a determination program for enabling one or more processors to execute the determination method according to claim 7.
